(19) United States
(12) Patent Application Publication
(10) Pub. No.: US 2025/0379167 A1
(43) Pub. Date: Dec. 11, 2025

(54) LIQUID METAL INTERCONNECTS FOR POWER SEMICONDUCTOR MODULES

(71) Applicant: The Board of Trustees of The University of Alabama, Tuscaloosa, AL (US)

(72) Inventor: Nicholas Baker, Tuscaloosa, AL (US)

(21) Appl. No.: 19/230,392

(22) Filed: Jun. 6, 2025

Related U.S. Application Data
(60) Provisional application No. 63/657,159, filed on Jun. 7, 2024.

(51) Int. Cl. H01L 23/00; H01L 23/31; H01L 23/498

(52) U.S. Cl. CPC H01L 24/05; H01L 24/03; H01L 24/37; H01L 24/40; H01L 23/3107; H01L 23/49861; H01L 2224/0331; H01L 2224/03848; H01L 2224/04034; H01L 2224/05139; H01L 2224/05144; H01L 2224/05155; H01L 2224/05164; H01L 2224/05166; H01L 2224/05169; H01L 2224/05181; H01L 2224/05605; H01L 2224/05609; H01L 2224/05611; H01L 2224/05613; H01L 2224/05639; H01L 2224/05644; H01L 2224/05664; H01L 2224/05669; H01L 2224/05705; H01L 2224/37639; H01L 2224/37644; H01L 2224/37655; H01L 2224/37664; H01L 2224/37666; H01L 2224/37669; H01L 2224/37681; H01L 2224/40227

(57) ABSTRACT

The disclosed subject matter relates to liquid metal interconnects for power semiconductor modules. For example, disclosed herein are semiconductor package devices, comprising: a semiconductor device comprising an electrode and/or contact pad; a solid metal circuit element; and a liquid metal interface comprising a liquid metal material. The liquid metal interface can append at least a portion of the solid metal circuit element to at least a portion of the electrode and/or contact pad within a contact area. Adhesive forces, cohesive forces, surface tension forces, capillary forces, viscosity, and/or wetting characteristics enable containment of the liquid metal interface within the contact area. Also disclosed herein are methods of making and use of any of the devices disclosed herein.

### CROSS-REFERENCE TO RELATED APPLICATIONS

This application claims the benefit of priority to U.S. Provisional Application No. 63/657,159 filed Jun. 7, 2024, which is hereby incorporated herein by reference in its entirety.

### BACKGROUND

The semiconductor packaging industry faces various technical challenges, particularly concerning efficient and reliable electrical connections in integrated circuits (ICs). Improved compositions, devices, and methods are needed. The compositions, devices, and methods discussed herein address these and other needs.

### SUMMARY

In accordance with the purposes of the disclosed compositions, devices, and methods as embodied and broadly described herein, the disclosed subject matter relates to liquid metal interconnects for power semiconductor modules.

For example, disclosed herein are semiconductor package devices, comprising: a semiconductor device comprising an electrode and/or contact pad; a solid metal circuit element; and a liquid metal interface comprising a liquid metal material. The liquid metal interface can append at least a portion of the solid metal circuit element to at least a portion of the electrode and/or contact pad within a contact area. Adhesive forces, cohesive forces, surface tension forces, capillary forces, viscosity, and/or wetting characteristics enable containment of the liquid metal interface within the contact area.

In some examples, the liquid metal material comprises an alloy comprising gallium, indium, tin, bismuth, or a combination thereof.

In some examples, the liquid metal material comprises a room temperature liquid metal material, a low temperature liquid metal material, or a combination thereof.

In some examples, the device comprises a first liquid metal interface comprising a first liquid metal material and a second liquid metal interface comprising a second liquid metal material. In some examples, the first liquid metal material transitions between liquid and solid at a first temperature, and the second liquid metal material is transitions between liquid and solid at second temperature, the first temperature being different than the second temperature.

In some examples, the liquid metal interface has a thickness of 25 μm or less. In some examples, the liquid metal interface has a thickness of 10 micrometers or less.

In some examples, the liquid metal interface has a thickness and/or composition that varies.

In some examples, the liquid metal material further comprises filler particles, such that the liquid metal material resembles a paste or foam. In some examples, the liquid metal material comprises a Ga-based paste.

In some examples, the liquid metal material comprises Ga and an additional metal such as palladium platinum, gold, silver, or a combination thereof.

In some examples, the portion of the semiconductor device and solid metal circuit element contacting the liquid metal interface are further coated with a metallization layer that enhances liquid metal wetting, enhances the adhesive force applied to the liquid metal interface material, prevents absorption of the liquid metal into the surface, or a combination thereof. In some examples, the metallization layer comprises gold, silver, tantalum, titanium, platinum, palladium, nickel, or a combination thereof. In some examples, at least a portion of the semiconductor device and solid metal circuit element are not in contact with the liquid metal interface, said portion of the semiconductor device and solid metal circuit element not contacting the liquid metal interface have a surface treatment or coating that reduces the adhesive force and wettability of the liquid metal interface material therewith.

In some examples, the device further comprises a lead frame and an electrically conductive connection device, where a first liquid metal interface appends at least a portion of the semiconductor device to at least a portion of the electrically conductive connection device, and where a second liquid metal interface appends at least a portion of the semiconductor device to at least a portion of the lead frame.

In some examples, the device further comprises an encapsulation material that encapsulates at least a portion of the semiconductor device and liquid metal interface.

In some examples, the device further comprises a pressure device configured to apply a pressure to at least a portion of the device.

Also disclosed herein are methods of making any of the devices disclosed herein.

In some examples, the method comprises, in the following order: pre-wetting liquid metal interface contact areas with liquid metal, aging the liquid metal contact areas to induce intermetallic formation prior to assembly, re-wetting at least one liquid metal contact area, and joining at least one liquid metal contact area.

In some examples, the liquid metal contact areas are wetted and joined in order of highest melting temperature first.

Additional advantages of the disclosed compositions, devices, and methods will be set forth in part in the description which follows, and in part will be obvious from the description. The advantages of the disclosed compositions, devices, and methods will be realized and attained by means of the elements and combinations particularly pointed out in the appended claims. It is to be understood that both the foregoing general description and the following detailed description are exemplary and explanatory only and are not restrictive of the disclosed compositions, devices, and methods, as claimed.

The details of one or more embodiments of the invention are set forth in the accompanying drawings and the description below. Other features, objects, and advantages of the invention will be apparent from the description and drawings, and from the claims.

### BRIEF DESCRIPTION OF THE FIGURES

The accompanying figures, which are incorporated in and constitute a part of this specification, illustrate several aspects of the disclosure, and together with the description, serve to explain the principles of the disclosure. However, the present disclosure is not limited to the precise arrangements shown, and the drawings are not necessarily drawn to scale.

FIG. 1. Schematic illustration of an example device as disclosed herein according to one implementation.

FIG. 2. Schematic illustration of an example device as disclosed herein according to one implementation.

FIG. 3. Schematic illustration of an example device as disclosed herein according to one implementation.

FIG. 4. (Left panel) Cross-section schematic of a traditional semiconductor package and the CTE of different materials. (Right panel) Photographs of example devices with aluminum wire-bonds (upper) and copper wire-bonds (lower).

FIG. 5. Schematic illustration of crack-formation and “lift-off” failures.

FIG. 6. Photographs of example wire-bonds and wire-bond variants.

FIG. 7. Photographs of example wire-bond lift-off failures.

FIG. 8. Schematic illustration of fundamental liquid metal interconnect (LMI) principle.

FIG. 9. SiC MOFSET Temperature Cycles to Failure.

FIG. 10A-FIG. 10B. Two examples of a liquid metal interface semiconductor package using a lead frame.

FIG. 11A-FIG. 11E. Examples of a liquid metal interface semiconductor package using a power substrate.

FIG. 12A-FIG. 12B. Further examples of a liquid metal interface semiconductor package using a power substrate, an electrically conductive connection device with a dielectric layer, and a solid metal spacer.

FIG. 13A-FIG. 13D. Examples of a liquid metal interface semiconductor package including power terminals used as a pressure device.

FIG. 14A-FIG. 14C. A state-of-the-art power substrate with a dielectric layer and two conductive layers, and a liquid metal interface-based power substrate with the dielectric layer and conductive layer joined with a liquid metal interface.

FIG. 15A-FIG. 15C. A semiconductor device with surface modifications to enable liquid metal interfaces.

FIG. 16. A manufacturing process flow chart for an example of a liquid metal interface power semiconductor module.

FIG. 17. Thermo-mechanical failures of top-side power semiconductor interconnects [6].

FIG. 18A-FIG. 18D. Images of LM-1 on 200 V Silicon diode. (FIG. 18A) schematic of LM-1. (FIG. 18B) Photo of LM-1 showing Ga on topside. (FIG. 18C) Ga leak causing short circuit. (FIG. 18D) Ga topside after power cycling.

FIG. 19A-FIG. 19B. (FIG. 19A) Ga on Ti barrier layer of Al metallized IGBT. (FIG. 19B) Barrier layer rupture on Si diode after power cycling.

FIG. 20. Calibration of V_{CE}(T) of LM-1 after successive calibration routines.

FIG. 21. Cycles to failure for LM-1 and Al wirebonded diodes during power cycling.

FIG. 22A-FIG. 22C. LM-2 on a Si IGBT. (FIG. 22A) LM-2 prior to power cycling.

(FIG. 22B) Corrosion of topside after power cycling. (FIG. 22C) Corrosion of topside after power cycling.

FIG. 23. Cycles to failure for LM-2 and Al wirebonded Si IGBTs during power cycling.

FIG. 24. Basic principle of Ga-based paste for LIME packaging.

FIG. 25. Cross section schematic of LIME (not to scale).

FIG. 26A-FIG. 26B. Pre-aging of Cu interfaces prior to assembly. Intermetallic formation can be viewed. (FIG. 26A). Indium-copper intermetallic. (FIG. 26B) Gallium-copper intermetallic.

FIG. 27A-FIG. 27C. (FIG. 27A) LIME-1 Si diode without pressure devices. (FIG. 27B). LIME-1 Si diode with pressure devices. (FIG. 27C) SAC305 and Al wirebonded diode.

FIG. 28. R_{TH(J-A)} measured at 24 A for LIME-1 vs. Al wirebond and SAC305 packaging on a silicon diode (6 samples each).

FIG. 29. Z_{TH} at 7-milliseconds measured at 24 A for LIME-1 vs. Al wirebond and SAC305. Error bars represent standard deviation.

FIG. 30. Power cycling test results for LIME vs. aluminum wirebonds and SAC305 solder.

FIG. 31A-FIG. 31C. (FIG. 31A) Pump-out of Field's metal to the topside of Cu clip [23]. (FIG. 31B) Die-attach interface after power cycling. (FIG. 31C) Cu clip interfaces after power cycling (corrosion at Field's metal interface).

FIG. 32. Cooling rate from an R_{TH(J-A)} measurement pre- and post-power cycling of LIME-1.

FIG. 33A-FIG. 33B. LIME-2 after power cycling. (FIG. 33A) Ga-paste at die-attach and power terminal interface. (FIG. 33B). Ga-paste at DBC-to-baseplate interface.

FIG. 34. R_{TH(J-A)} vs. power dissipation for LIME-2 and SAC305 and Al wirebonded Sic MOSFET.

FIG. 35. Z_{TH} at 7-milliseconds vs. power dissipation on a SiC MOSFET.

FIG. 36. Evolution of V_{ON} and ΔT_{J} from one sample of LIME-2 during a power cycling test.

FIG. 37A-FIG. 37B. Topside of LIME-2-SiC MOSFET after power cycling. (FIG. 37A) Whisker growth from the chip surface. (FIG. 37B) Corrosion at the clip and chip interface.

FIG. 38A-FIG. 38C. Corrosion of Indium-based LMs on the topside of a SiC MOSFET at different stages during power cycling. (FIG. 38A). After 10k cycles. (FIG. 38B) After 50k cycles. (FIG. 38C) At end-of-life (147 kcycles).

FIG. 39A-FIG. 39C. Ga-paste die-attach before and after power cycling. (FIG. 39A) Pre-assembly. (FIG. 39B) After power cycling. (FIG. 39C) Scratched with a tweezer to reveal LM underneath.

FIG. 40 shows a liquid-metal interface contact area. In some cases, the surface metals at the contact area may be of non-planar (i.e., of differing thickness) and/or materials.

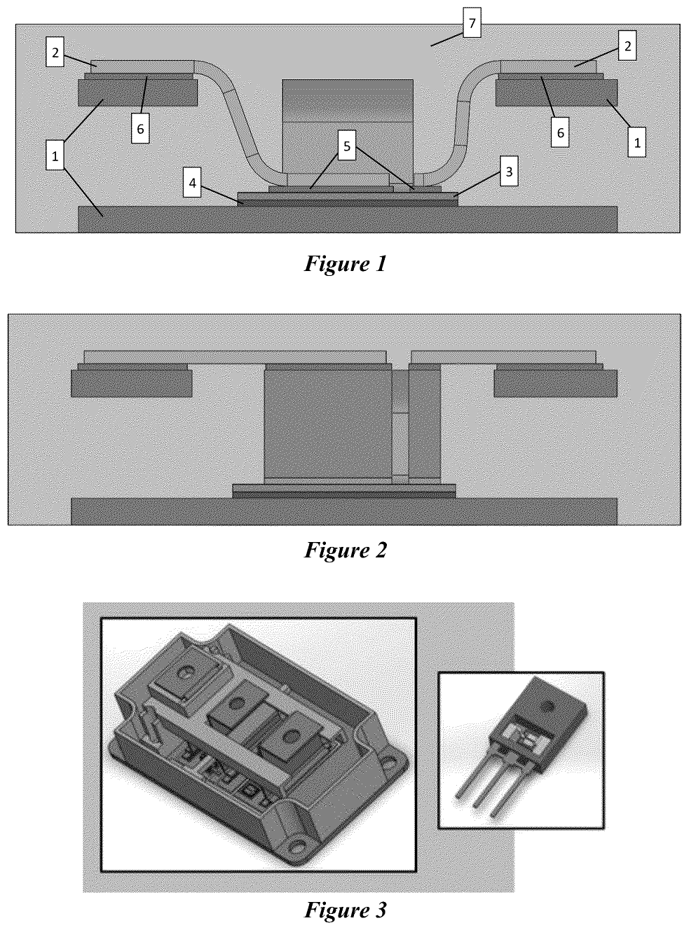

### DETAILED DESCRIPTION

The compositions, devices, and methods described herein may be understood more readily by reference to the following detailed description of specific aspects of the disclosed subject matter and the Examples included therein.

Before the present compositions, devices, and methods are disclosed and described, it is to be understood that the aspects described below are not limited to specific synthetic methods or specific reagents, as such may, of course, vary. It is also to be understood that the terminology used herein is for the purpose of describing particular aspects only and is not intended to be limiting.

Also, throughout this specification, various publications are referenced. The disclosures of these publications in their entireties are hereby incorporated by reference into this application in order to more fully describe the state of the art to which the disclosed matter pertains. The references disclosed are also individually and specifically incorporated by reference herein for the material contained in them that is discussed in the sentence in which the reference is relied upon.

### General Definitions

In this specification and in the claims that follow, reference will be made to a number of terms, which shall be defined to have the following meanings.

Throughout the description and claims of this specification the word “comprise” and other forms of the word, such as “comprising” and “comprises,” means including but not limited to, and is not intended to exclude, for example, other additives, components, integers, or steps. As used in the specification and in the claims, the term “comprising” can include the aspects “consisting of” and “consisting essentially of.”

As used in the description and the appended claims, the singular forms “a,” “an,” and “the” include plural referents unless the context clearly dictates otherwise. Thus, for example, reference to “a composition” includes mixtures of two or more such compositions, reference to “an agent” includes mixtures of two or more such agents, reference to “the component” includes mixtures of two or more such components, and the like.

“Optional” or “optionally” means that the subsequently described event or circumstance can or cannot occur, and that the description includes instances where the event or circumstance occurs and instances where it does not.

Ranges can be expressed herein as from “about” one particular value, and/or to “about” another particular value. By “about” is meant within 5% of the value, e.g., within 4, 3, 2, or 1% of the value. When such a range is expressed, another aspect includes from the one particular value and/or to the other particular value. Similarly, when values are expressed as approximations, by use of the antecedent “about,” it will be understood that the particular value forms another aspect. It will be further understood that the endpoints of each of the ranges are significant both in relation to the other endpoint, and independently of the other endpoint.

Throughout this disclosure, various aspects of the invention can be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, a description of a range such as from 1 to 6 should be considered to have specifically disclosed subranges such as from 1 to 3, from 1 to 4, from 1 to 5, from 2 to 4, from 2 to 6, from 3 to 6, etc., as well as individual numbers within that range, for example, 1, 2, 2.7, 3, 4, 5, 5.3, 6 and any whole and partial increments therebetween. This applies regardless of the breadth of the range.

When the specific values are disclosed between two end values, it is understood that these end values can also be included.

For the terms “for example” and “such as,” and grammatical equivalences thereof, the phrase “and without limitation” is understood to follow unless explicitly stated otherwise. It is further understood that these phrases are not used in a restrictive sense, but for explanatory purposes. “Exemplary” means “an example of” and is not intended to convey an indication of a preferred or ideal embodiment.

It is understood that throughout this specification the identifiers “first” and “second” are used solely to aid in distinguishing the various components and steps of the disclosed subject matter. The identifiers “first” and “second” are not intended to imply any particular order, amount, preference, or importance to the components or steps modified by these terms.

As used herein, the term “and/or” includes any and all combinations of one or more of the associated listed items.

As used herein, the term “substantially” means that the subsequently described event or circumstance completely occurs or that the subsequently described event or circumstance generally, typically, or approximately occurs.

Still further, the term “substantially” can, in some aspects, refer to at least about 80%, at least about 85%, at least about 90%, at least about 91%, at least about 92%, at least about 93%, at least about 94%, at least about 95%, at least about 96%, at least about 97%, at least about 98%, at least about 99%, or about 100% of the stated property, component, composition, or other condition for which substantially is used to characterize or otherwise quantify an amount.

In other aspects, as used herein, the term “substantially free,” when used in the context of a composition or component of a composition that is substantially absent, is intended to refer to an amount that is then about 1% by weight, e.g., less than about 0.5% by weight, less than about 0.1% by weight, less than about 0.05% by weight, or less than about 0.01% by weight of the stated material, based on the total weight of the composition.

The expressions “ambient temperature” and “room temperature” as used herein are understood in the art and refer generally to a temperature from about 20° C. to about 35° C.

References in the specification and concluding claims to parts by weight of a particular element or component in a composition denotes the weight relationship between the element or component and any other elements or components in the composition or article for which a part by weight is expressed. Thus, in a mixture containing 2 parts by weight of component X and 5 parts by weight of component Y, components X and Y are present at a weight ratio of 2:5 and are present in such a ratio regardless of whether additional components are contained in the mixture.

A weight percent (wt. %) of a component, unless specifically stated to the contrary, is based on the total weight of the formulation or composition in which the component is included.

A volume percent (vol %) of a component, unless specifically stated to the contrary, is based on the total volume of the formulation or composition in which the component is included.

While aspects of the present invention can be described and claimed in a particular statutory class, such as the system statutory class, this is for convenience only and one of ordinary skill in the art will understand that each aspect of the present invention can be described and claimed in any statutory class. Unless otherwise expressly stated, it is in no way intended that any method or aspect set forth herein be construed as requiring that its steps be performed in a specific order. Accordingly, where a method claim does not specifically state in the claims or descriptions that the steps are to be limited to a specific order, it is in no way intended that an order be inferred in any respect. This holds for any possible non-express basis for interpretation, including matters of logic with respect to the arrangement of steps or operational flow, plain meaning derived from grammatical organization or punctuation, or the number or type of aspects described in the specification.

Unless otherwise defined, all technical and scientific terms used herein have the same meaning as commonly understood by one of ordinary skill in the art to which this invention belongs.

### Devices Comprising Liquid Metal Interconnects

Described herein are devices comprising liquid metal interconnects.

For example, described herein are semiconductor package devices, comprising: a semiconductor device comprising an electrode and/or contact pad; a solid metal circuit element; and a liquid metal interface comprising a liquid metal material; wherein the liquid metal interface appends at least a portion of the solid metal circuit element to at least a portion of the electrode and/or contact pad within a contact area; wherein adhesive forces, cohesive forces, surface tension forces, capillary forces, viscosity, and/or wetting characteristics enable containment of the liquid metal interface within the contact area.

As used herein, a “liquid metal material” describes metals that maintain liquid phase at a given temperature.

In some examples, during operation of the device, the liquid metal interface transitions between solid- and liquid-phase.

The liquid metal material can comprise any suitable metal consistent with the description herein. In some examples, the liquid metal material comprises an alloy comprising gallium, indium, tin, bismuth, or a combination thereof.

In some examples, the liquid metal material comprises a room temperature liquid metal material, a low temperature liquid metal material, or a combination thereof.

As used herein, a “a room temperature liquid metal material” describes metals that maintain liquid phase at room temperature.

As used herein, a “low temperature liquid metal material” describes metals that maintain liquid phase at a temperature above room temperature but at or below the operating temperature of the device. For example, the low temperature liquid metal interface can therefore transition to liquid state by the normal operating power losses and temperature fluctuations of the semiconductor device. In some examples, the low temperature liquid metal is not melted through the normal operation of the semiconductor device, but via a predefined power loss routine designed to raise the temperature to the melting point of the low temperature liquid metal.

In some examples, the device comprises a first liquid metal interface comprising a first liquid metal material and a second liquid metal interface comprising a second liquid metal material, wherein the first liquid metal material and the second liquid metal material are the same or different.

In some examples, the first liquid metal material transitions between liquid and solid at a first temperature, and the second liquid metal material transitions between liquid and solid at second temperature, the first temperature being different than the second temperature.

In some examples, the first liquid metal material comprises a room temperature liquid metal material, a low temperature liquid metal material, or a combination thereof.

In some examples, the second liquid metal material comprises a room temperature liquid metal material, a low temperature liquid metal material, or a combination thereof.

In some examples, the first liquid metal material comprises a first room temperature liquid metal material and the second liquid metal material comprises a second room temperature liquid metal material.

In some example, the first liquid metal material comprises a first low temperature liquid metal material and the second liquid metal material comprises a second low temperature liquid metal material.

In some example, the first liquid metal material comprises a room temperature liquid metal material, and the second liquid metal material comprises a low temperature liquid metal material.

In some examples, the liquid metal interface has a thickness of 25 micrometers (μm, microns) or less (e.g., 20 μm or less, 15 μm or less, 10 μm or less, 5 μm or less, or 1 μm or less). In some examples, the liquid metal interface has a thickness of 20 μm or less. In some examples, the liquid metal interface has a thickness of 10 μm or less.

In some examples, the liquid metal interface has a thickness and/or composition that varies. For example, the device can use different thicknesses and/or different materials across the liquid metal interface, so that the edges around the liquid metal interface become solid and protect it from the environment.

In some examples, the liquid metal material comprises Ga (e.g., pure Ga or an alloy comprising Ga). In some examples, the liquid metal material comprises Ga and an additional metal such as palladium platinum, gold, silver, or a combination thereof. The additional metal can, for example, be selected to raise the melting point of the liquid metal material above room temperature.

In some examples, the liquid metal material further comprises filler particles, such that the liquid metal material resembles a paste or foam. In some examples, the liquid metal material comprises a Ga-based paste, such as a Ga-based paste comprising gallium oxide filler particles.

In some examples, the paste or foam can further include additional additives, for example that can simplify the deposition and/or dispensing of the liquid metal material. The additional additives can, for example, then be evaporated after application of the paste or foam.

In some examples, the portion of the semiconductor device and solid metal circuit element contacting the liquid metal interface are further coated with a metallization layer that enhances liquid metal wetting, enhances the adhesive force applied to the liquid metal interface material, prevents absorption of the liquid metal into the surface, or a combination thereof. In some examples, the metallization layer comprises gold, silver, tantalum, titanium, platinum, palladium, nickel, or a combination thereof.

In some examples, at least a portion of the semiconductor device and solid metal circuit element are not in contact with the liquid metal interface, said portion of the semiconductor device and solid metal circuit element not contacting the liquid metal interface have a surface treatment or coating that reduces the adhesive force and wettability of the liquid metal interface material therewith.

In some examples, the device further comprises a lead frame and an electrically conductive connection device, where a first liquid metal interface appends at least a portion of the semiconductor device to at least a portion of the electrically conductive connection device, and where a second liquid metal interface appends at least a portion of the semiconductor device to at least a portion of the lead frame.

In some examples, the device further comprises one or more additional components. The one of more of the components can be joined using an interconnect. In some examples, all of the interconnects comprise liquid metal interfaces.

In some examples, the device further comprises an encapsulation material that encapsulates at least a portion of the semiconductor device and liquid metal interface. The encapsulation material can comprise any suitable encapsulation material consistent with the description herein. In some examples, the encapsulation material comprises a soft, flexible, or low shore hardness encapsulation material; a high shore hardness encapsulation material; or a combination thereof.

In some examples, the device further comprises a pressure device configured to apply a pressure to at least a portion of the device.

In some examples, the device exhibits improved lifetime relative to a device using a solid metal interface in place of the liquid metal interface.

In some examples, the devices can use different thicknesses and/or different materials across the surface metal in the contact area, so that the edges around the liquid become solid and protect it from the environment.

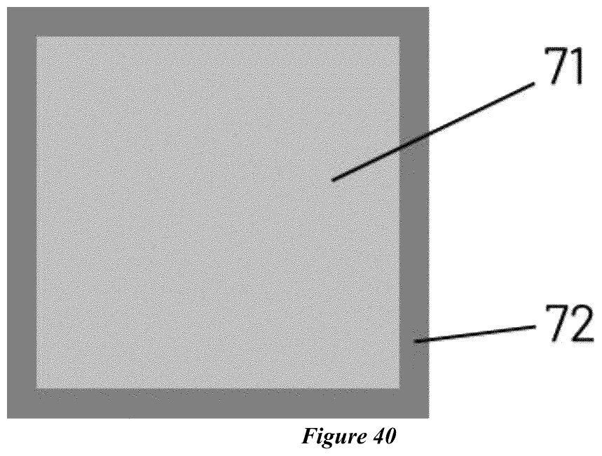

FIG. 40 shows a liquid-metal interface contact area. In some cases, the surface metals at the contact area can be non-planar (i.e., of differing thickness) and/or differing materials. In FIG. 40, 71 can be a surface metal of a lower-thickness, while 72 can be a surface metal of a higher thickness. In this case, the intermetallic formation with the liquid-metal material can be altered according to the location across the surface.

As a result, the intermetallic formation can be formed in a way that 72 forms a high-melting solid intermetallic, with 71 remaining a liquid-phase intermetallic. Therefore, 72 forms a hermetic seal around the liquid-metal material.

In some examples, the device comprises a Si diode, a Si IGBT, a SiC MOSFET, or a combination thereof.

Also described herein are articles of manufacture comprising any of the devices described herein. Examples include, but are not limited to, electric vehicles, power supplies, and inverters. In some example, the article comprises a train, aircraft, energy device, elevator, production line, mining device, oil rig, electric vehicles, wind turbine, or combination thereof. In some examples, the article comprises an electrified transport, an article for electricity generation/distribution, industrial machinery, or a combination thereof.

### Methods of Making

Also disclosed herein are methods of making any of the devices disclosed herein. In some examples, the method comprises, in the following order: pre-wetting liquid metal interface contact areas with liquid metal; aging the liquid metal contact areas, for example at an elevated temperature, to induce intermetallic formation prior to assembly; re-wetting at least one liquid metal contact area; and joining at least one liquid metal contact area. In some examples, liquid metal contact areas are wetted and joined in order of highest melting temperature first.

A number of embodiments of the invention have been described. Nevertheless, it will be understood that various modifications may be made without departing from the spirit and scope of the invention. Accordingly, other embodiments are within the scope of the following claims.

The examples below are intended to further illustrate certain aspects of the systems and methods described herein, and are not intended to limit the scope of the claims.

### EXAMPLES

The following examples are set forth below to illustrate the methods and results according to the disclosed subject matter. These examples are not intended to be inclusive of all aspects of the subject matter disclosed herein, but rather to illustrate representative methods and results. These examples are not intended to exclude equivalents and variations of the present invention which are apparent to one skilled in the art.

Efforts have been made to ensure accuracy with respect to numbers (e.g., amounts, temperature, etc.) but some errors and deviations should be accounted for. Unless indicated otherwise, parts are parts by weight, temperature is in ° C. or is at ambient temperature, and pressure is at or near atmospheric. There are numerous variations and combinations of measurement conditions, e.g., component concentrations, temperatures, pressures and other measurement ranges and conditions that can be used to optimize the described process.

### Example 1

Described herein is a liquid metal based semiconductor packaging technique. All interconnections in the package are made with liquid metals. Currently, the technology achieves 37× lifetime when stressed in industry standard aging tests in comparison to the global state-of-art.

The technology also improves nominal power density by approximately 10%. This means the size of the silicon chips can be reduced by 10%, or the mass and volume of overall power electronic systems inside vehicles, wind turbines, PV, etc.

The actual increase in power density will be larger than 10%, since semiconductors are designed according to their required lifetime. Lifetime is a function of power in the module. Higher power will generally mean lower lifetime. With a 37× increase in lifetime, the technology can reduce the costs of a silicon carbide power module by 75%.

Another advantage is the production process is performed at lower temperatures (e.g., below 70 degrees C.) and lower pressure, compared to over 250 degrees C. in industry state of art. This is a significant advantage in terms of energy required for production, chemicals required, and cleaning steps. Low temperature and low pressure production processes also enable the choice of more favorable materials which would otherwise be damaged at high temperature. High temperature production processes warp materials. High pressure production processes increase the chances of cracking. The liquid metal manufacturing process does not have these problems, which can lead to higher yield and higher performance modules.

Advantages include, but are not limited to:
Increased thermomechanical lifetime, possibly by several orders of magnitude
Increases power density by approximately 10%
Low temperature manufacturing process

The technology can reduce the cost of a silicon carbide power module by 75%.

For example, a SiC power module in the 600V+ range can be made using only liquid metal interconnects.

### Example 2—Liquid Metals Interconnect for Power Semiconductors Modules

The semiconductor packaging industry faces various technical challenges, particularly concerning efficient and reliable electrical connections in integrated circuits (ICs).

Traditional approaches like soldering and wire bonding, while prevalent, encounter limitations such as mechanical stress, thermal mismatch, and potential reliability issues over long-term usage or under fluctuating thermal conditions. Soldered joints, for instance, can suffer from electromigration and thermal fatigue, leading to failure in electronic devices.

Wire bonding, on the other hand, although widely used for its simplicity and low cost, can experience issues like bond wire lift and breakage under mechanical or thermal stress. These challenges underscore the need for innovative materials and methods that can provide robust, thermally stable, and mechanically flexible connections to accommodate the increasingly high-power densities and miniaturization trends in modern electronic components.

Moreover, with the ongoing evolution towards more compact and integrated systems, ensuring excellent electrical connectivity while also managing heat effectively remains a hurdle.

Described herein is a liquid interconnect semiconductor package that features several innovative aspects improving the functionality and reliability of semiconductor device connections. The package comprises a semiconductor device with multiple electrodes, a solid metal lead frame, and solid metal electrically conductive connection devices.

Unique to this system are two distinct types of liquid metal interface materials: one that operates at room temperature, appending the semiconductor's electrodes to the lead frame, and another that functions above room temperature, activated by the device's normal operational heat, to link the semiconductor's electrodes with the terminals of the conductive connection devices.

This dual liquid metal system allows for more flexible thermal management and dynamic response to temperature fluctuations without a permanent solid state bond, enhancing mechanical stress tolerance. The package can further be encapsulated in a protective material, enhanced by different material properties in specific areas for optimized protection and performance, reinforcing the structural integrity while catering to the unique needs of liquid metal interfaces.

Such a configuration is innovative as it not only improves electrical connections but also adapts to temperature changes and operational demands dynamically, distinguishing it from traditional solder-based or solid-metal connection approaches which are static and less adaptive to thermal and mechanical variations.

Described herein is a liquid metal-based semiconductor packaging technique. All interconnections in the package are made with liquid metals. Currently the technology achieves 37× lifetime when stressed in industry standard aging tests in comparison to the global state-of-art.

Advantages include, but are not limited to:
Increases thermochemical lifetime, possibly by several orders of magnitude
Increases power density by approximately 10%
Low temperature manufacturing process
Reduce the costs of a Silicon Carbide power module by 75%
Liquid metal (LM) packaging reduces the thermal resistance of the chip by approximately 10%

Applications include, but are not limited to, SIC MOSFET power modules in the 600V+ range using only liquid metal interconnects.

SiC MOSFETs are widely used in high-power applications such as electric vehicles, power supplies, and inverters due to their ability to operate at high frequencies, voltages, and temperatures while maintaining efficiency.

The liquid metal interface described would greatly benefit these devices by enhancing thermal management through superior heat conduction, crucial for maintaining performance and reliability under high-operating temperatures and minimizing thermal resistance and improving the heat dissipation from the active device to the cooling systems or the environment, thus possibly allowing for higher power densities

Power semiconductors are the primary component in terms of weight, volume, and cost.

Improved thermal management: The use of a low, above room temperature, liquid metal interface material that transitions to a liquid state under normal operating conditions, such as power losses and temperature fluctuations, enables better thermal conductivity compared to traditional soldered connections.

Enhanced mechanical flexibility: The liquid metal interfaces provide a flexible connection between semiconductor devices and their lead frames or electrically conductive devices. This flexibility can reduce stress and fatigue failures commonly associated with rigid solder joints found in conventional semiconductor packaging.

Reduced interconnect thickness: The invention can achieve liquid metal interfaces below 25 μm in thickness, providing tighter package densities and potentially reducing overall package size compared to traditional methods like wire bonding or flip-chip technology.

Controlled interface transformation: The apparatus allows for the control of the interface material state by a predefined power loss routine. This precision in controlling the transition of the liquid metal material to the operating temperature, which is not commonly found in typical semiconductor devices such as those using solid solder, enables more reliable and predictable performance.

Superior surface metallization: Pre-aged surface metallization with intermetallic formation enhances the reliability and durability of contacts by improving the wetting properties and mitigating the absorption of the liquid metal into the device surfaces, compared to those that might use unoptimized surface treatments.

### Example 3—Liquid Metal Based Power Semiconductor Packaging

Semiconductor packaging connects the chip to the outside world. All power semiconductor packaging processes use ultrasonic, thermosonic, or thermocompression bonding (i.e., solid metals are physically welded together). These interconnects are degraded by thermomechanical stress and are the primary failure cause in power semiconductors. A solution to this can be the use of liquid metals, which are not susceptible to thermomechanical stress.

An example device is shown in FIG. 3:
Multi-chip high power: 1200-450 A
Industry standard package to minimize barriers to customers

Advantages include, but are not limited to:
40× increased lifetime
10% improved thermal resistance
Low temperature manufacturing (70° C. vs. 250° C.+)
Low pressure manufacturing (0.2 MPa vs. 5 MPa+)
75% reduction in cost of power semiconductor modules

Power semiconductors are the fundamental component in power electronics. They are found in trains, aircraft, energy, elevators, production lines, mining, oil rigs, electric vehicles, wind turbines, etc. Power semiconductors are the primary component in terms of weight, volume, and cost. An electric vehicle has a power semiconductor content of over $1000. A wind turbine can have a power semiconductor content of $20,000 to $60,000.

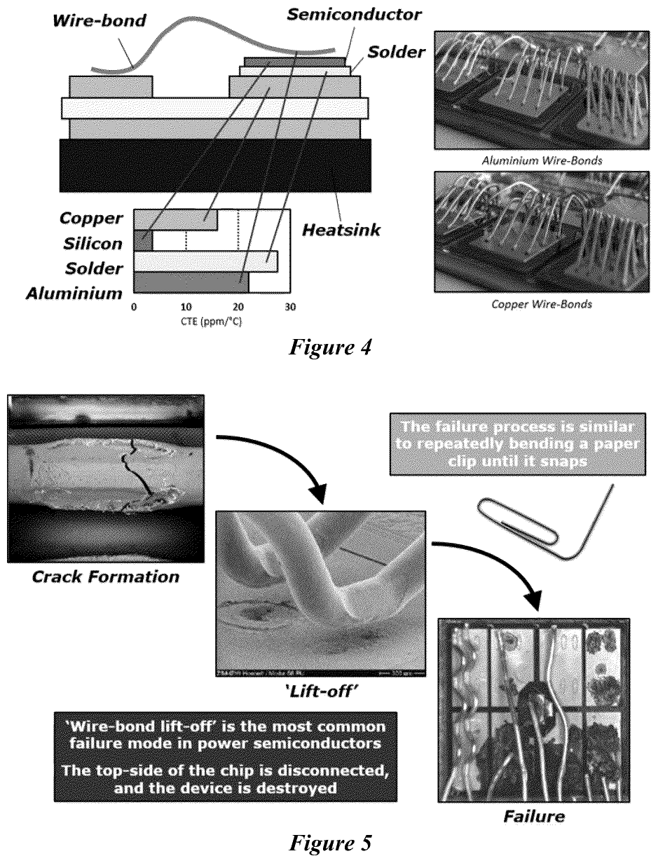

The most common failure mechanism in a semiconductor panel is due to the thermomechanical stress on the packaging materials. This is due to differences in the coefficients-of-thermal-expansion (CTE) of each material. Each material expands and contracts at different rates according to the operating temperature. A cross-section schematic of a traditional semiconductor package and the CTE of different materials is shown in the left panel of FIG. 4. Photographs of example devices with aluminum wire-bonds and copper wire-bonds are also shown in the upper and lower right panels of FIG. 4, respectively.

Repeated thermal cycling leads to cracks and eventual lift-off of the wire-bond from the semiconductor chip itself (FIG. 5). The same process occurs in all state-of-the-art semiconductor interconnect technologies. Failure process is similar to repeatedly bending a paperclip until it snaps. “Wire-bond lift-off” is the most common failure mode in power semiconductors. The top side of the chip is disconnected and the device is destroyed.

The most common failure mechanism is “wire-bond lift-off.” Wire bonding accounts for 90%+ of all semiconductor interconnections. Over 20 trillion wire-bonds are manufactured annually. Reliability and optimization of wire-bonding is a major topic in semiconductor R&D. Many wire-bond technology variants exist. But all are affected by the same thermomechanical failure process.

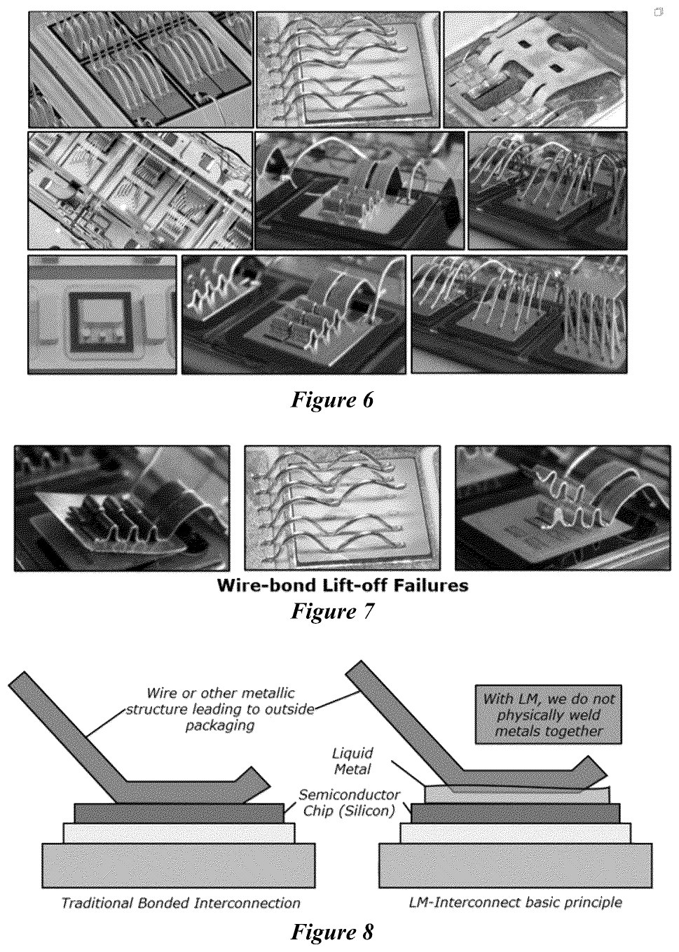

Photographs of example wire-bonds and wire-bond variants are shown in FIG. 6. Photographs of example wire-bond lift-off failures are shown in FIG. 7.

Described herein, liquid metal (LM) replaces the wire bond process in power modules. With liquid metal interconnects (LMI), metals are not physically welded together (FIG. 8). Liquid metal is not subject to thermomechanical stress. It can theoretically expand and contract a large number of times without causing cracking or liftoff.

Lifetime Increase (liquid standard vs. Industry standard): The liquid metal interconnect package described herein can increase the lifetime by 37.5× (3745%) relative to an industry standard (SAC305 solder and aluminum wirebonds). The percent increase in average lifetime was normalized to the average lifetime of industry standard samples. The samples were aged in an industry standard power cycling test.

Comparison to industry advanced packaging (SiC MOSFET): Industry advanced interconnect technologies are primarily based in solver/copper sintering, and copper wirebonding.

A like-for-like comparison was performed for the technology described here versus industry advanced packaging.

The results from Streibel et al. were used for the industry advanced packaging (Reliability SiC MOFSET with Danfoss Bond Buffer Technology in Automotive Traction Power Modules, PCIM Europe 2019, International Exhibition and Conference for Power Electronics, Intelligent Motion, Renewable Energy and Energy Management, Nuremberg, Germany, 2019, pp. 1-7).

Test conditions in Streibel et al. included a Single SiC Chip with 2 out of 3 layers substituted with “advanced” packaging (silver sinter and copper wirebonds). The results for the industry advanced packaging showed a 2.73× lifetime increase and a 13% improvement in R_{TH} compared to industry standard.

However, the liquid metal technology described herein outperforms the industry advanced packaging in a comparable study, as shown in Table 1.

TABLE 1
Like-for-like comparison of liquid metal and industry
advanced packaging vs. Industry standard.

| | LM | Industry |
|---|---|---|
| | standard | Advanced |
| Lifetime | >37.5X | 2.75X |
| Thermal Resistance | 10-14% | 13% |

Benefits of Reliability: Power modules are sized based on the expected lifetime of the system (e.g., 5, 10, 20 years). For example, consider an elevator with a desired lifetime of 10 years and an average of 100 elevator trips per day. This gives an average total number of elevator trips over 10 years of 356,000. The average power per each trip is 500 W (per power module).

For current industry standard modules, the maximum temperature swing per trip to survive 356,000 trips is 39° C. (Hoffmann et al. “Lifetime Modeling of SiC MOFSET Power Modules During Power Cycling Tests at Low Temperature Swings,” 2023 35th International Symposium on Power Semiconductor Devices and ICs (ISPSD), Hong Kong, 2023, pp. 294-297). This gives a required SiC module thermal resistance of 0.079° C./W (39° C. divided by 500 W). For these parameters, the SiC module cost is about $2713 (based on Mouser's Wolfspeed 1200V SiC MOSFET Pricing vs. R_{TH} data).

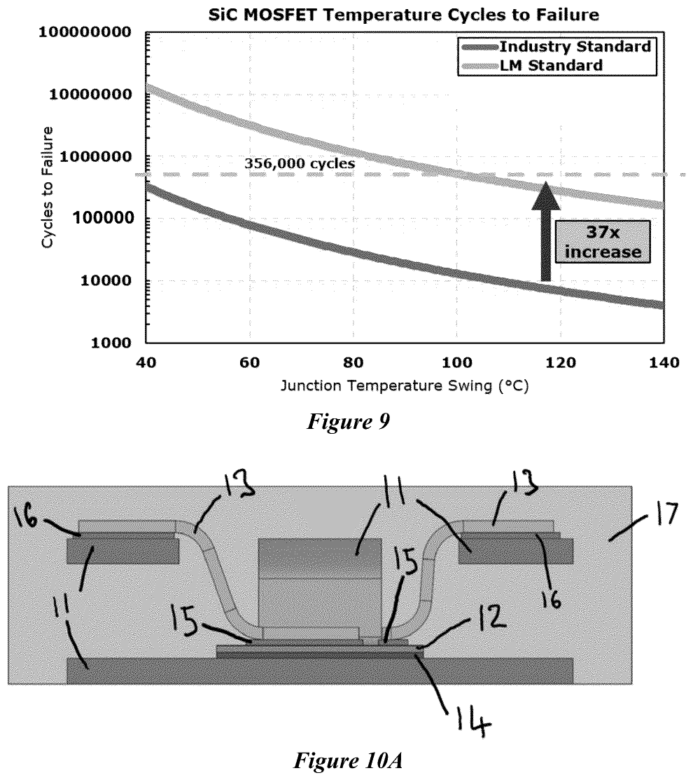

Meanwhile, the liquid metal technology described herein shows an improvement of 37× in thermal cycling reliability. The maximum temperature swing per trip to survive 356,000 trips for the LM standard is therefore 112° C. (FIG. 9). Thus, the required SiC module thermal resistance is 0.224° C./W (112° C. divided by 500 W). For these parameters, the SiC module cost is about $689 (based on Mouser's Wolfspeed 1200V SiC MOSFET Pricing vs. R_{TH} data).

Thus, using the liquid metal technology described herein, the SiC module cost can be reduced by 75%.

### Example 4—Liquid Metal Interconnects for Power Semiconductor Modules

Disclosed herein are liquid metal interconnects for power semiconductor modules.

For example, described herein is a liquid interconnect semiconductor package, comprising: at least one semiconductor device with at least two electrodes; at least one solid metal lead frame; at least one solid metal electrically conductive connection device; a room temperature liquid metal interface material that appends at least one electrode of the semiconductor device to the lead frame; a low, above room temperature, liquid metal interface material that appends at least one electrode of the semiconductor device to at least one terminal of at least one electrically conductive connection device, with the above room temperature liquid metal interface being transitioned to liquid state by the normal operating power losses and temperature fluctuations of the semiconductor device; at least one electrically conductive connection device having at least one terminal attaching to a lead frame through a liquid metal interface material; and an encapsulation material that encapsulates the semiconductor device, and liquid metal interfaces.

In some examples, the liquid metal interfaces are below 25 μm in thickness.

In some examples, the above room temperature liquid metal is not melted through the normal operation of the semiconductor device, but via a predefined power loss routine designed to raise the temperature to the melting point of the above-room-temperature-liquid-metal.

In some examples, the liquid metal interface materials contain filler particles such that the liquid metal interface material resembles a paste or foam.

In some examples, a room temperature liquid metal appends the semiconductor device to the electrically conductive connection device, and the above-room-temperature-liquid-metal appends the semiconductor device to the lead frame.

In some examples, both the lead frame and the electrically conductive connection device are appended to the semiconductor with a room temperature liquid metal In some examples, both the lead frame and the electrically conductive connection device are appended to the semiconductor with an above room temperature liquid metal.

In some examples, the encapsulation material comprises two materials: a soft, flexible, or low shore hardness encapsulation surrounding the semiconductor device and liquid metal interfaces, and a high shore hardness encapsulation material surrounding the electrically conductive connection device and part of the lead frame.

In some examples, the surface metallization of the lead frame, electrically conductive connection device, and semiconductor device, are provided pre-aged with intermetallic formation from the reaction of the surface metal with the liquid metal interface material. This may be performed on only the desired contact surfaces or on the entire surface of the devices.

In some examples, the lead frame and electrically conductive connection device, and contact surfaces on the semiconductor device are coated with a layer such as Nickel, Gold, Silver, Tantalum, Titanium, or other material, that enhances liquid metal wetting or prevents absorption of the liquid metal into these devices.

In some examples, semiconductor device surface metallization is removed and replaced by a layer of liquid metal, that wets the barrier metal layer. The semiconductor device may be surrounded by a polyimide guard ring in the region of 0 μm-100 μm in height.

In some examples, the liquid metal materials are alloy based, for example a combination or Gallium, Indium, or Bismuth alloys.

In some examples, a solid metal electrically conductive spacer is sandwiched between at least one electrically conductive connection device and the semiconductor device. The spacer is appended to the semiconductor device and the electrically conductive connection device via at least one layer of liquid metal.

In some examples, a solid metal electrically conductive spacer is sandwiched between the lead frame and the semiconductor device. The spacer is appended to the semiconductor device and the lead frame via at least one layer of liquid metal.

In some examples, the semiconductor package undergoes a burn-in process, through vibration or thermal cycling, or other suitable method, to induce wetting of the liquid metal interface to the contact surfaces.

In some examples, all liquid metal interface contact surfaces are pre-wetted with liquid metal via scrubbing, mechanical vibration, laser sintering, or other suitable method, prior to assembly.

In some examples, where the lead frame is substituted for a power substrate with a ceramic or flexible polymer insulation material.

### Example 5—Solid-Liquid Metal Interface Power Semiconductor Module

Abstract. Described herein are power device packages constructed using one or more liquid metal interfaces. In some examples, the package uses a semiconductor device, a power substrate, a solid metal electrically conductive connector device, a solid metal electrically conductive spacer, a pressure device, a power terminal, a baseplate, and a housing. All elements are joined using liquid metal interfaces. The package can contain numerous liquid metal interface materials, which transition between liquid and solid at differing temperatures. At some temperatures therefore, the package can contain both solid and liquid interfaces.

The invention relates to power electronic devices, replacing interconnects such as wirebonding, soldering, sintering, conductive epoxy, or other solid interconnect techniques, with liquid metal interfaces. This improves the reliability of power electronic devices by several orders of magnitude.

Introduction. Semiconductor devices require interconnects and packaging materials to interface with the outside world. For power semiconductor devices in particular, the interconnects and packaging materials are a primary source of failure.

Common interconnect technologies include wirebonding, soldering, sintering, and ultrasonic welding. Almost all prior interconnect technologies contain some form of thermal, thermosonic, ultrasonic, or thermo-compression joining technique. That is, solid materials are joined together, usually under high temperature.

Materials for these interconnects are typically as follows for power devices. Wirebonding can primarily comprise copper or aluminum wirebonds, Sintering can use silver or copper sinter pastes, and solders can be lead-based or un-leaded. Furthermore, the semiconductor chip can be silicon, silicon carbide, gallium nitride, diamond, or another semiconductor material. The power substrate can also contain a dielectric and conductive layer of rigid or flexible material. In some cases, a rigid or flexible encapsulation from epoxy or silicone gel can also be used.

Each of the above materials in the device construction has a different coefficient-of-thermal-expansion. Thermal cycling leads to thermo-mechanical stress that causes cracking, lift-off, and separation of these materials. Reliability of these joints can be improved via optimization of the manufacturing process; however, all these interconnect joints are susceptible to cracking from thermo-mechanical stress.

A further issue is that the manufacturing process for these interconnections typically requires high temperature, which limits the choice of materials and thicknesses. For example, power module baseplates and power substrates can warp and crack during the high temperature process of soldering or sintering. As a result, this warping must be compensated for prior to manufacture. This can include pre-bent baseplates, thicker baseplate thicknesses (which increases thermal resistance and material costs), and/or selection of dielectric materials which are able to withstand the stress of the manufacturing process but may have inferior thermal conductivity.

Surface cleanliness and roughness are also issues in traditional interconnect technologies such as sintering or soldering. For sintering, the surface must be clean, and the roughness controlled to avoid cracking of the devices at the high pressure sometimes required (which can be over 10 MPa). For any process that requires high temperature, oxidation of materials becomes a problem, and the atmosphere must be controlled. In addition, soldering usually requires a vacuum to remove voids in the interface.

In some cases, pressure contacts are also used, but require high pressure to ensure good electrical and thermal contacts to handle the required current levels (which in power devices can often be over 50 A). This can induce other failure modes, such as fretting.

Liquid metals on the other hand are not susceptible to cracking from thermomechanical stress. In addition, the manufacturing process temperature for a liquid metal interface can be below the operating temperature of the device, and therefore any residual stress remaining from manufacturing can be removed as the liquid metal interface materials transition from solid to liquid during device operation. Basic surface cleaning such as removal of surface oxide and use of alcohol wipes is often sufficient for the manufacturing process. Hazardous chemicals and high pressure are also generally not required. This has several advantages for the reliability and efficiency of power devices. In addition, pressure contacts can be made with lower pressure.

Many in the art will assume that the use of liquid metal in a device will require recesses, cavities, special encapsulations, and/or floating/flexible structures, to contain the liquid. In addition, some may envision that liquid metal wires/conductors are used to directly replace wirebonds, busbars, or other wired connections inside a power package.

Liquid metal indeed has many applications for conductors in flexible or stretchable electronics. For example, U.S. Pat. No. 11,955,253B2 describes stretchable liquid metal conductors encased microfluidic channels. In U.S. Pat. No. 10,879,151B2, a potentially flexible semiconductor package is described using liquid metal conductors.

In U.S. Pat. No. 9,728,868B1, a power device package is described using a cavity and a lid to encase a phase changing material (liquid metal) connecting to a top-side contact of an electrical device.

However, herein, a power semiconductor device package is described using liquid metal interfaces. Liquid metal conductors/wires, or cavities to contain the liquid metal are not required, though they can in some examples be present. The devices described herein can also be referred to as a solid-liquid hybrid interface device since some examples can entail the use of multiple liquid metal interface materials with differing melting points. Therefore, the package can contain both solid and liquid metal interfaces that transition between these states at different operating points and temperatures.

Summary A semiconductor package and manufacturing method using liquid metal interfaces is described herein. In some examples, the package contains one or more semiconductor devices, a power substrate with a dielectric layer and a conductive layer, a solid metal electrically conductive connector device with a dielectric layer and a conductive layer, a solid metal electrically conductive spacer, an electrically conductive pressure device, and a baseplate. All elements are joined using liquid metal interfaces. The package contains a room temperature liquid metal interface material, and an above room temperature liquid metal interface material which transitions to liquid phase during operation of the semiconductor device. The liquid metal interface materials can also resemble a paste, foam, and/or contain solid particles.

The liquid metal interface materials are constrained by enhancing the adhesive force applied to the liquid metal in the desired interface contact areas through selection of the surface metallization or treatment. In addition, the bondline thicknesses are minimized, for example to less than 20 μm and preferably less than 10 μm, so that the adhesive, cohesive, and surface tension forces enable containment of the liquid metal within the contact area. In addition, minimization of the bondline thicknesses to magnitudes of less than 10 μm can overcome the inferior thermal conductivity of liquid metals in comparison to solder or sinter materials and achieve a comparable thermal resistance.

In fact, even if cavities or “swimming pools” are used, liquid metal can ascend the sides of a cavity and escape due to the nature of liquid metal wetting characteristics and intermetallic formation.

Also described herein are manufacturing methods for a liquid metal interface-based semiconductor package. In the following description, both a room temperature and an above room temperature liquid metal is used. It is acknowledged that these materials can be used interchangeably. The method comprises:
1. Supplying the package components (such as power substrate, connector device, semiconductor device, etc.) with surface coating or metallization that enhances the adhesive force or wetting of liquid metal on the desired interface areas. In non-interface areas, the metallization can be chosen to decrease adhesive force and/or wetting of the liquid metal.
2. Cleaning or removing oxides from interface surfaces.
3. Applying and wetting the liquid metal interface material to the desired interface areas and pre-aging the components to induce intermetallic formation prior to assembly.
4. Cleaning the interface surfaces of excess liquid metal from step 3.
5. Wetting at least one electrode of the electrically conductive connection device, at least one electrode of the semiconductor device, and one electrode of a solid metal electrically conductive spacer, with an above room temperature liquid metal interface material.
6. Joining at least one electrode of the electrically conductive connection device to at least one electrode of the semiconductor device and one electrode of the solid metal spacer, using the above room temperature liquid metal interface material.
7. Applying a first encapsulation partially encapsulating the semiconductor device and electrically conductive connection device above room temperature liquid metal interface, leaving unwetted electrode pads exposed.
8. Wetting the power substrate, the baseplate, a second electrode of the semiconductor device, and a second electrode of the solid metal spacer, with a room temperature liquid metal interface material.
9. Pressing the electrically conductive connection device, the semiconductor device, the solid metal spacer, and the power substrate, in the direction of the baseplate, using a pressure device.
10. Applying a second encapsulation.

Brief Description of Figures. The invention is described using the following figures. Since the actual thickness of the liquid metal interface layers can be below 10 μm, the figures are not drawn to scale. The liquid metal interface layers are shown larger to enable visibility.

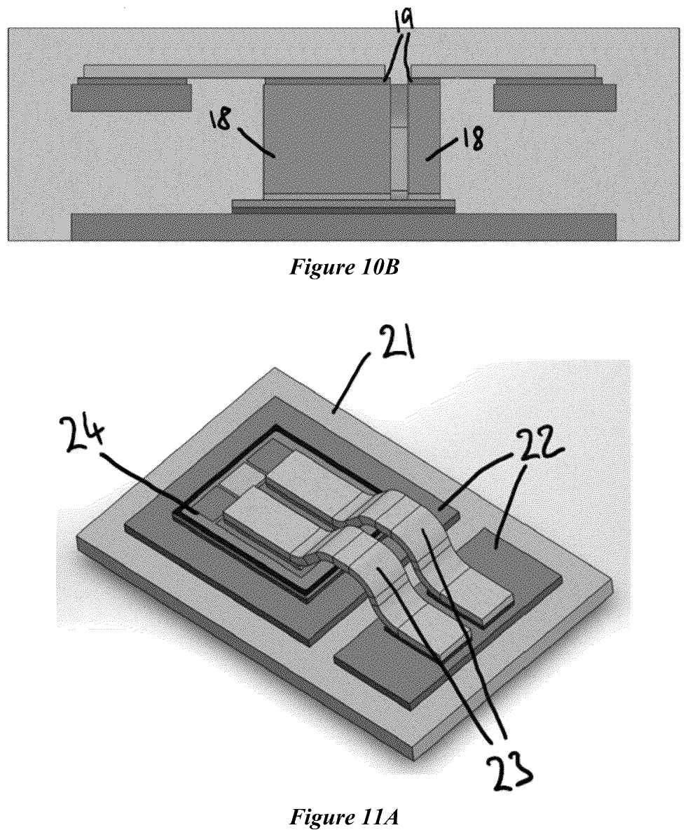

FIG. 10A-FIG. 10B shows two examples of a liquid metal interface semiconductor package using a lead frame.

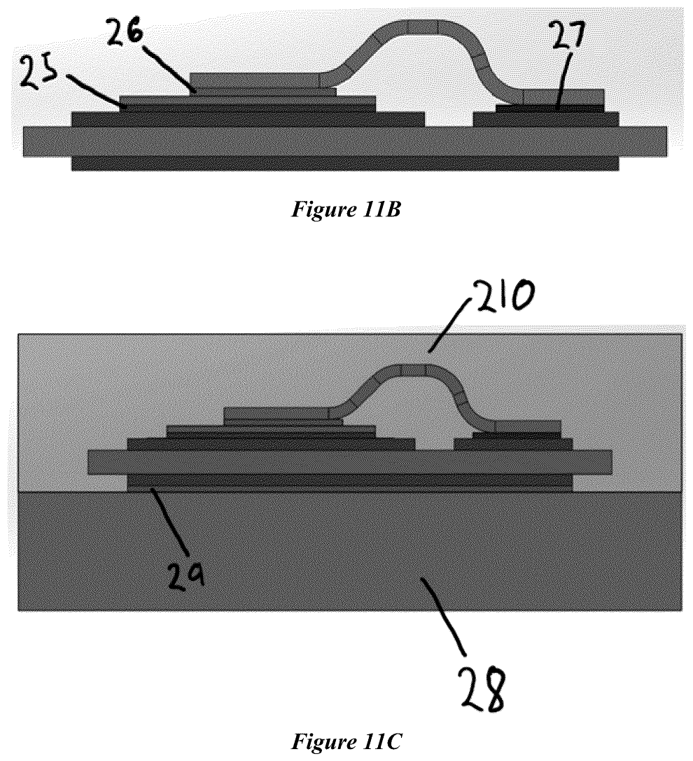

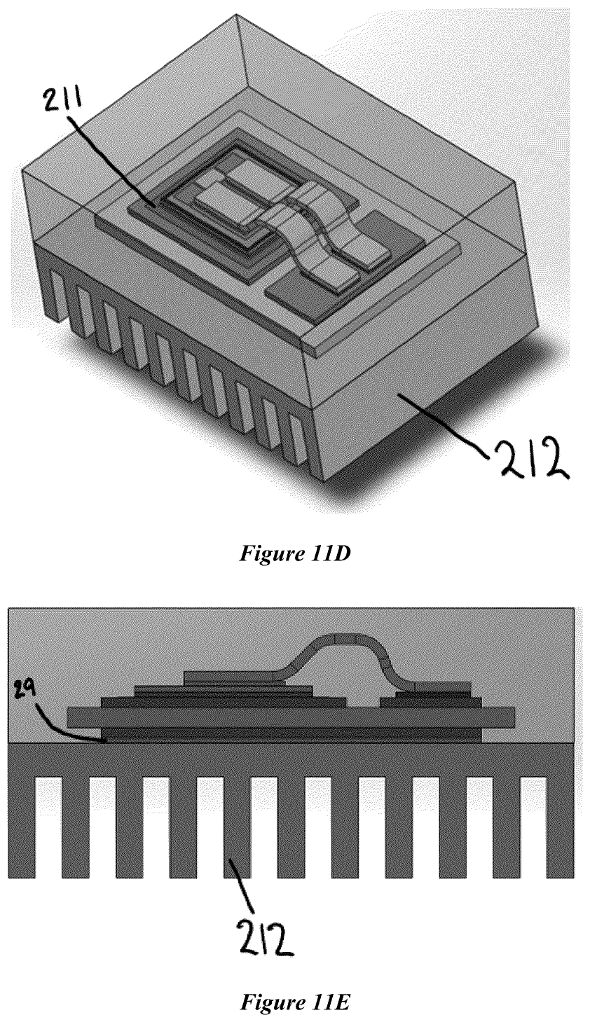

FIG. 11A-FIG. 11E shows several examples of a liquid metal interface semiconductor package using a power substrate.

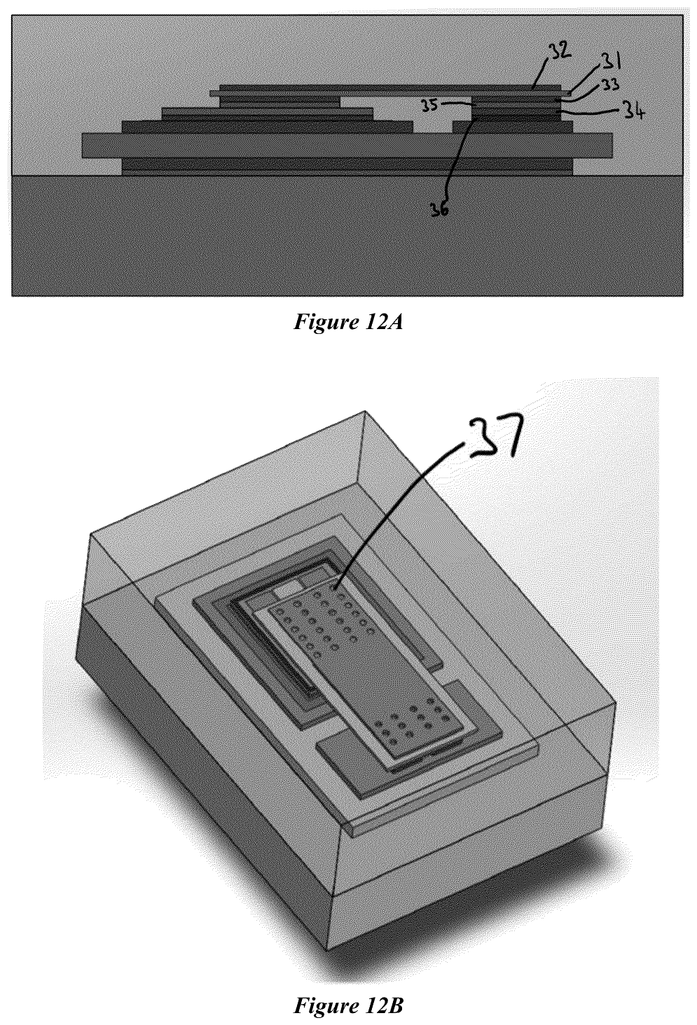

FIG. 12A-FIG. 12B shows further examples of a liquid metal interface semiconductor package using a power substrate, an electrically conductive connection device with a dielectric layer, and a solid metal spacer.

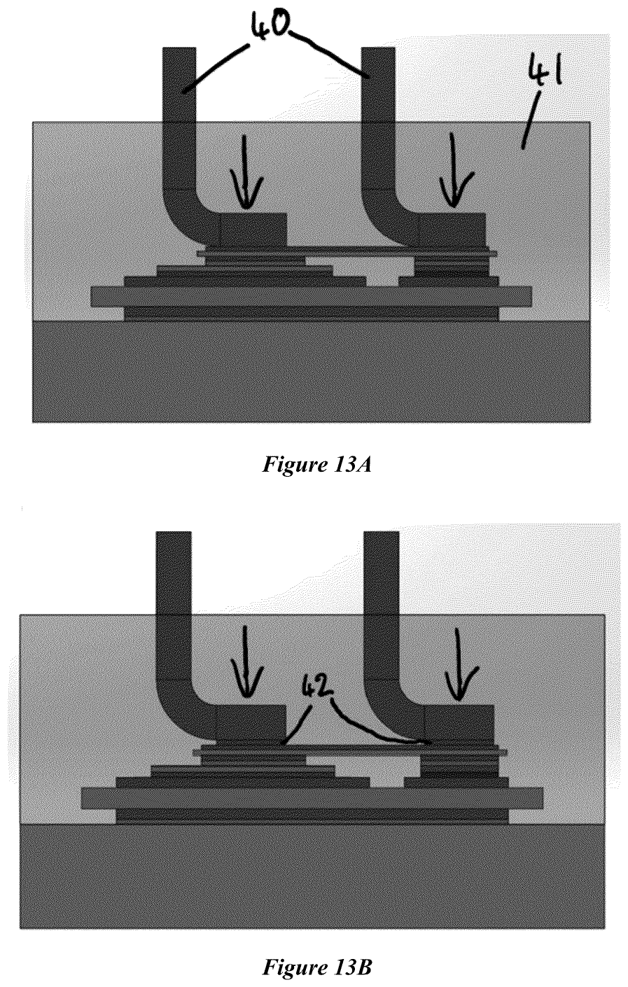

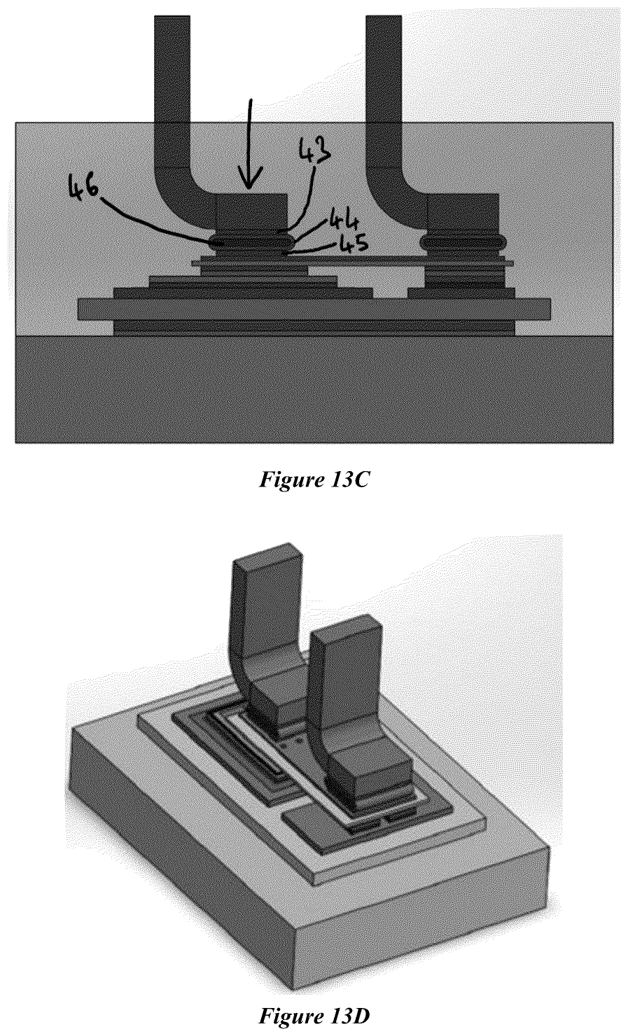

FIG. 13A-FIG. 13D shows examples of a liquid metal interface semiconductor package including power terminals used as a pressure device.

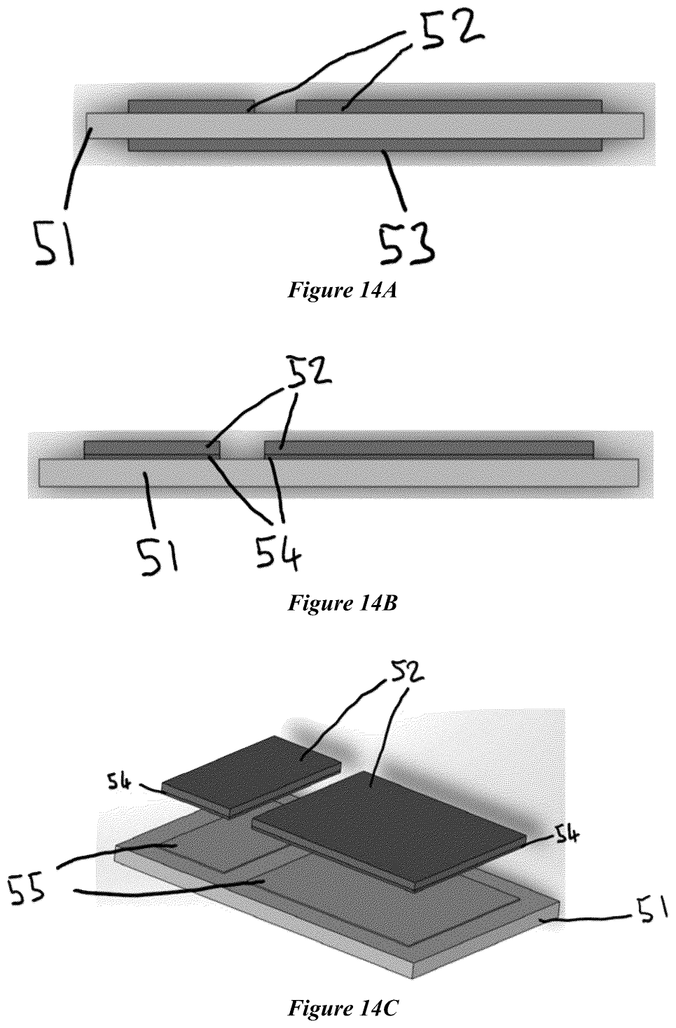

FIG. 14A-FIG. 14C shows a state-of-the-art power substrate with a dielectric layer and two conductive layers, and a liquid metal interface-based power substrate with the dielectric layer and conductive layer joined with a liquid metal interface.

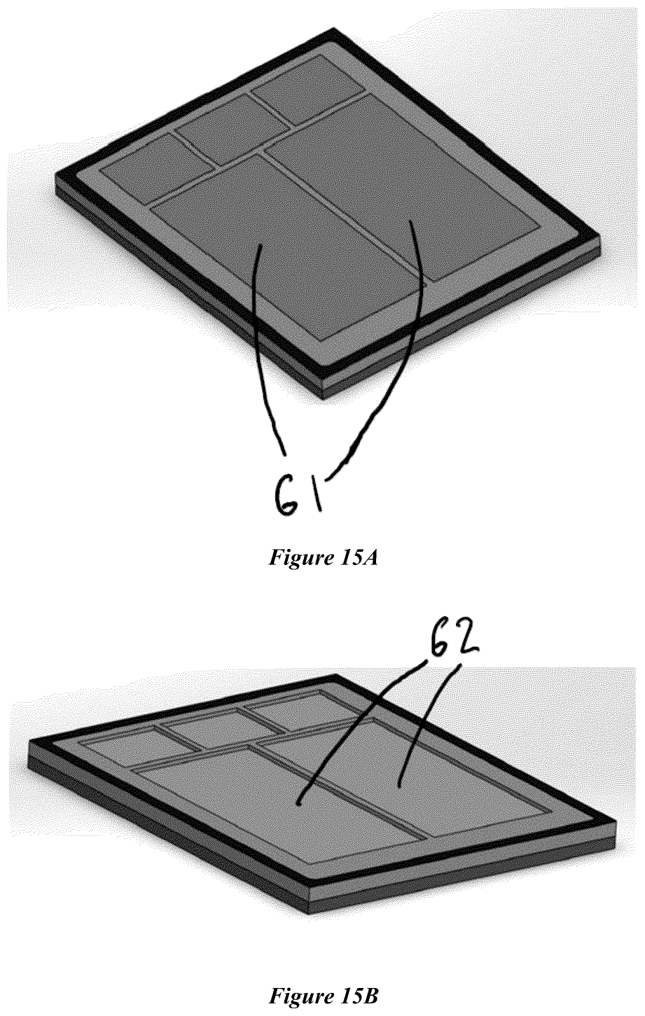

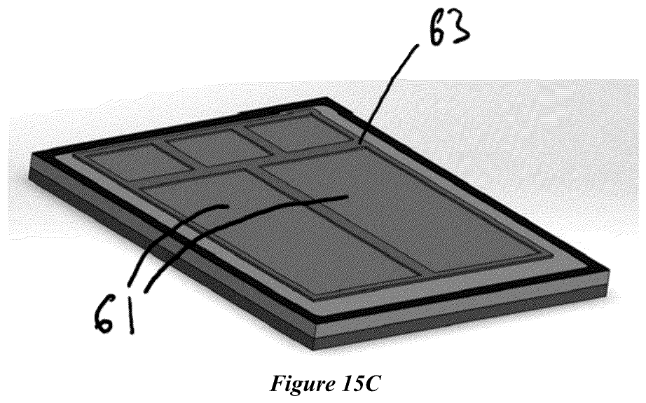

FIG. 15A-FIG. 15C shows a semiconductor device with surface modifications to enable liquid metal interfaces.

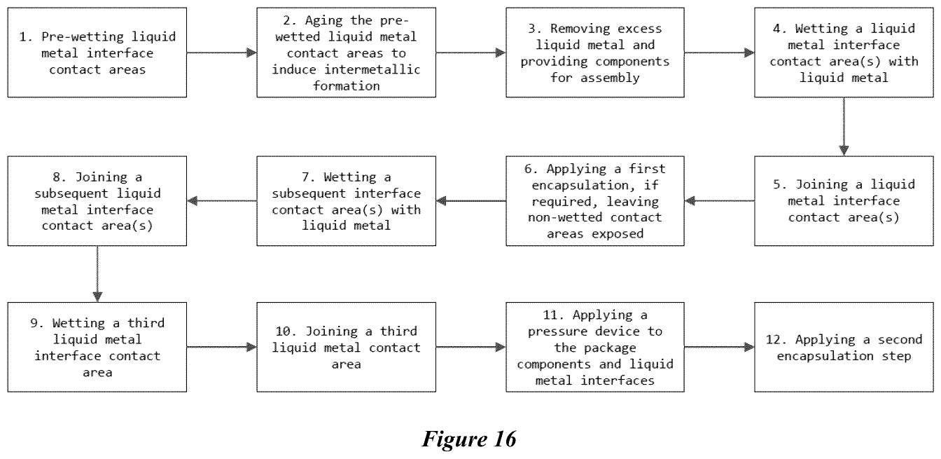

FIG. 16 shows a manufacturing process flow chart for an example of a liquid metal interface power semiconductor module.

Detailed Description of Figures. The invention is depicted in the figures using a single semiconductor device, however the invention can be applied to paralleled semiconductors, discrete devices, multi-chip type modules, half-bridge, full-bridge modules, and so forth. The semiconductor device can be a diode, MOSFET, IGBT, Thyristor, or another transistor or electrical device having at least one electrode.

The invention is depicted in the figures on a vertically conducting semiconductor device with at least one bottom-side electrode and one topside electrode. However, the invention can be applied to horizontally conducting devices, such as gallium nitride MOSFETs, using the same techniques.

An object of the invention is to replace solid interfaces with liquid metal interfaces.

FIG. 10A displays an example with three liquid metal interfaces: 14, 15, and 16. FIG. 10A additionally shows a lead frame 11, a semiconductor device 12, a solid metal electrically conductive connection device 13, and an encapsulation material 17. The lead frame 11 can be substituted for a power substrate.

The bottom-side electrode of the semiconductor device 12 is appended to the lead frame through liquid metal interface material 14. The topside electrode of the semiconductor device is appended to a solid metal electrically conductive connection device 13 through liquid metal interface material 15. The electrically conductive connection device 13 is appended to the lead frame 11 through liquid metal interface material 16. An encapsulation material 17 encapsulates the semiconductor device 12, liquid metal interfaces 13, 14, and 15, the electrically conductive connection device 13, and part of the lead frame 11 so that the lead frame can function as power terminals to the device.

In some examples, each liquid metal interface can comprise a different material that transitions from solid to liquid at different temperatures. For example, liquid metal interface materials 15 and 16 can have a melting point above room temperature, while 14 can have a melting point below room temperature. This has some practical benefits.

First, the manufacturing process can be simplified. In the above case, the lead frame 11, electrically conductive connection device 13, and top-side contact of the semiconductor device 12, can be joined in a process temperature above room temperature. The components can be cooled down to below room temperature to solidify the interface materials. The parts can then be fixed together and can be easily transferred to the next process step. Liquid metal interface materials in their solid state do not provide the bond strength of a traditional interconnect material, especially at the sub-10 μm bondline thickness described herein, however the bond strength is enough to withstand subsequent manufacturing steps.

In the next manufacturing step, the semiconductor device 12 (with the attached electrically conductive connection device 13) can be appended to the lead frame 11 at room temperature via liquid metal interface material 14. Depending on the package geometry, manufacturing can be simpler if some room temperature liquid metal interfaces are joined first.

As a result, the package can contain both solid and liquid interfaces at certain temperatures. In the case an above room temperature liquid metal is selected, it can have a melting temperature within the normal operating range of the device and be routinely melted during normal operation. Alternatively, the melting point can be achieved by providing a defined power loss routine to raise the operating temperature of the semiconductor device to the melting temperature. This could, for example, be done during system maintenance routines, or when damage to the solid interface is suspected. The ambient temperature can also be raised to transition the interface to liquid and repair damage.

One aspect of the devices described herein is that each contact surface for a liquid metal interface is pre-wetted with liquid metal prior to assembly. Pre-wetting of the semiconductor bottom electrode and top electrode is challenging if both interface materials are liquid at the same temperature. On the other hand, if one material melts at a higher temperature, this material can be applied to one electrode first and then solidified. The semiconductor device (and any attached parts) can then be flipped over to pre-wet the next electrode with a lower temperature liquid metal. This process can be made easier by using planar structures for the electrically conductive connection device.

If both top and bottom side electrodes of the semiconductor device contact a liquid metal with the same melting temperature, special fixtures can be used to pre-wet both top and bottom electrodes. Alternatively, encapsulation can be performed in numerous process steps. For example, one semiconductor electrode can be wetted and appended to the desired part (e.g., a connection device or a lead frame). Next, a partial encapsulation step can be used that encases the semiconductor device (and any attached parts on the wetted electrode) but leaves the unwetted electrodes exposed for the next pre-wetting step.

Pre-wetting of contact surfaces is advantageous for several reasons. Wetting of surfaces by liquid metal is generally achieved by reactive wetting, or oxide wetting. The implications of this will be explained in the following paragraphs.

In reactive wetting, the liquid metal forms an alloy with the surface metal and it is this alloy that the liquid metal wets to. In most cases, this alloy is a solid and consumes part of the liquid metal. In some cases, the intermetallic can consume a significant amount of the applied liquid metal and the interface may no longer be liquid.

As a result, the contact surfaces herein can be pre-wetted and then pre-aged to form the intermetallic layer and consume part of the liquid metal. This process can be accelerated, for example, by baking the wetted contact surfaces at elevated temperatures. This temperature can be higher than the expected operating temperatures of the device. Once the intermetallic is formed, its thickness and growth becomes more stable after the initial aging. The contact area can be cleaned and liquid metal reapplied in the knowledge that the reapplied liquid metal will not be consumed by intermetallic formation. This has benefits for calculating the required amount of liquid metal to dispense per contact area.

In oxide wetting, it is the oxide layer of the liquid metal that wets the surface.

Wetting of contact surfaces in either the reactive or oxide case can be achieved by friction or scrubbing, mechanical vibration, laser or plasma sintering, chemically induced, or other methods.

If only one or no contact surface is provided pre-wetted, unstable thermal and electrical behavior of the interfaces has been observed. This instability usually subsides after a burn-in process involving thermal cycling of the package. Other burn-in procedures can include vibration or sonication after the device manufacture is completed.

There are many suitable surface metallizations for interface surfaces with good wetting properties including, copper, gold, silver, silver coated nickel, gold coated nickel, nickel palladium gold, tin, and others. For liquid metals that do not contain gallium, aluminum can be used. However, the wetting characteristics are poor and pump out of the liquid metal interface material during thermal cycling on aluminum contact areas has been observed.

Liquid metal pastes, foams, or solid/liquid hybrid materials can also be used. In the case of gallium, an oxide layer is formed instantly on contact with oxygen. This oxide layer is in the region of nanometers in thickness and can be easily broken. It is therefore possible to create paste like consistencies of the liquid metal by continually mixing and exposing gallium to oxygen so that the material is some part liquid and some part solid. This can increase the viscosity of the material, increase wetting performance, reduce pump out during thermal cycling, and can be easier to dispense. In the case of a gallium/oxide paste material, the thermal conductivity and the surface tension of the material is reduced, however the benefits provided by the mechanical properties of the paste can outweigh this reduction.

Other solid particles can be dispersed in the liquid metal materials to form a paste or foam like appearance, or to edit the thermal and electrical properties. The choice of particle size and material depends on the reactivity of the particle with the liquid metal, the wetting characteristics, and desired outcome. Some choices of particles will produce inferior characteristics and can also separate from the liquid metal during thermal cycling.

The viscosity and wetting characteristics of liquid metals and liquid metal pastes mean that without pre-wetting of the entire contact surface, only part of the contact area may ultimately be wetted and lead to increased thermal and electrical resistance. The devices described herein can however be manufactured without a pre-wetting step, if desired.

The use of multiple temperature liquid metal interface materials can also benefit practical operation of the device.

For instance, due to the nature of thermal spreading in power semiconductor devices, some operating conditions can see temperature gradients exceeding 40° C. across the semiconductor chip. In this situation, it is conceivable the temperature distribution across the chip can lead to part of the liquid interface layers being solid, and part of the layer being liquid. Since some liquid metals expand on solidification, this can lead to stresses placed on the semiconductor chip, pump out of the liquid interface material, and/or incomplete interface connection since the liquid portion of the interface is reduced in volume in comparison to the solid region.

In addition, in large area liquid metal interfaces, where some portion of the interface is liquid while another portion remains solid, pump out in the liquid portion has been observed.

In some examples, a gallium-indium-tin alloy or paste with a melting point of 11° C. can be used for one interface 14, while an indium-bismuth-tin alloy or paste with a melting point of 62° C. can be used for another interface 15. With a 51° C. difference in melting temperature, the 62° C. interface material can completely solidify before the 11° C. material in most operating conditions, reducing the likelihood of that regions of the semiconductor device 12 are joined through solid materials, while other regions are joined through liquid.

Nevertheless, other combinations of melting points can be used and liquid metal interface materials of the same type and melting temperature can be used for all interfaces in the devices described herein.

During device operation, the highest temperature swings are observed close to the semiconductor device 12 where the largest concentration of power losses exist. These interfaces 14 and 15 face the largest thermo-mechanical stress and are usually the first points of a failure in a power device. As a result, liquid metal interfaces 16 which append the lead frame 11 to the electrically conductive connection devices 13 (and are not in direct contact with the semiconductor device 12) can be substituted for a traditional solid interconnect technology such as soldering, sintering, welding, or another conductive adhesive. In some cases, the manufacturing process can be simplified without significant impacts on the device lifetime.

In fact, the use of only one liquid metal interface on the semiconductor device still has significant benefits to the lifetime of the device. For example, the lifetime of a semiconductor device with a sintered or soldered bottom side interface paired with a liquid metal topside interface can be increased by a factor of 5. The same lifetime increase can be expected in the reverse configuration with liquid metal bottom side interface, and a traditional solid interface on the topside.

Significant benefits can therefore be expected using only one liquid metal interface. However, the use of liquid metal at all interfaces in contact with the semiconductor electrodes can increase the lifetime of the device by a factor of over 50.

Since liquid metals can expand on solidification, the encapsulation material 17 can be a multi material encapsulation. For example, a soft flexible encapsulation can be used to encase the liquid metal interfaces so that the expansion on solidification is accommodated, while a hard rigid encapsulation can be used to encase the lead frame and the rest of the semiconductor package and provide mechanical support.

In FIG. 10B, another example of the device is presented. In this case, the device contains a solid metal electrically conductive spacer 18 that is sandwiched between the semiconductor device 12 and the solid metal electrically conductive connection device 13. This necessitates another interface 19 which can be a liquid metal interface material. This format allows the solid metal components in the device to be manufactured in a planar structure, which can have benefits for manufacturing tolerances of these parts.

The thermal conductivity of traditional solid interface materials such as sintering or soldering ranges between 60 W/mK for solder, and over 200 W/mK for sintering. Thermal conductivity for liquid metal interface materials is significantly lower, for example up to 30 W/mK for pure gallium. More realistically, thermal conductivities can be as low as 20 W/mK, although the thermal conductivity can be increased using solid particles dispersed in the liquid. As a result, the bondline thickness of the liquid metal interfaces must be kept to a minimum. Bondline thicknesses for solder and sintering can be up to 50 μm or more. The bondline thickness for liquid interface materials can be below 10 μm. Therefore, planar structures can be advantageous to accommodate these tolerances.

In addition, minimizing the bondline thickness has benefits for restraining the liquid metal interface material to the desired contact areas. The device primarily uses the adhesive and cohesive force and wetting characteristics of the contact area, and surface tension and viscosity of the liquid metal to restrain the material. Reducing the bondline thickness means that the force requirement to restrain the liquid metal interface material is reduced. Providing a pressure device (not shown in FIG. 10A-FIG. 10B but an example is shown in FIG. 13A-FIG. 13D) that presses the solid metal electrically conductive connection device 13, semiconductor device 12 in the direction of the lead frame 11 can further minimize bondline thickness.

FIG. 11A displays another example device. A semiconductor device 24 is appended to a power substrate with a dielectric layer 21 and a conductive layer 22. The topside electrode of the semiconductor device 24 is appended to a solid metal electrically conductive connection device 23. The solid metal electrically conductive connection device is further appended to the power substrate conductive layer 22. FIG. 11A shows an angled view.

FIG. 11B shows a cross section of the example device of FIG. 11A. Liquid metal interfaces 25, 26, and 27, are used to append the semiconductor device 24 and electrically conductive connection device 23 to the power substrate. As in prior examples, these interfaces can be of the same material or of different materials with different melting temperatures. Solid metal electrically conductive spacers can also be used in a similar manner as other examples.

FIG. 11C displays an example where the power substrate is appended to a baseplate 28. This example includes a further liquid metal interface layer 29. The device is surrounded by an encapsulation material 210. This encapsulation material can be soft or rigid, or made from multiple materials, as in other examples (e.g., FIG. 10A-FIG. 10B). Power terminals to the package are not shown in FIG. 11C.

Liquid metal interface 29 is typically a much larger area interface than those around the semiconductor device 24 or electrically conductive connection device 23. In prior art, the interface between the baseplate and power substrate is made using traditional solid interconnect technologies with a high process temperature. This induces warping of the baseplate and power substrate and can lead to cracking during the manufacturing process. As a result, the dimensions and shape of the baseplate is restricted and must be planned for prior to manufacture. With a liquid metal interface, this issue is eliminated. This allows a variety of baseplate designs to be used. For example, in FIG. 11D and FIG. 11E, the baseplate is replaced by a heatsink 212.

FIG. 11D shows a surface treatment 211 surrounding the semiconductor device 24. The principle is that the liquid metal interface contact surfaces are coated with a metallization or surface treatment that enhances the adhesive force applied to the liquid metal. For example, the semiconductor device 24 can be coated with silver coated nickel, gold coated nickel, gold pallidum nickel, on the bottom-side electrode. Copper and other metals can also be used. Similar metallizations can be used on the power substrate interface contact area. These metallizations provide a high adhesive force and wetting characteristics to the liquid metal.

In non-contact areas, it is possible to provide a metallization or surface treatment 211 that reduces the adhesive force applied to the liquid metal and wettability of the surface. In doing so, pump out of the liquid metal interface material is reduced. Those working in the field of liquid metals will observe that liquid metals will wet certain surfaces and materials preferentially over others. Some options for low adhesive force and poor wettability include, but are not limited to, aluminum (for non-gallium based liquid metal materials), nickel oxide, aluminum oxide, copper oxide, some types of graphene, some types of polymer, increasing the surface roughness, and/or other coatings including hydrophobic coatings or sprays. In some cases, solder mask can be sufficient. The selection of the surface modification can depend on the liquid metal interface material used.

FIG. 12A shows an example device where the electrically conductive connection device contains a dielectric layer 31 and conductive layers 32 and 33. The number of dielectric layers and conductive layers can be more than one. The electrically conductive connection device is planar in structure in FIG. 12A. A solid metal electrically conductive spacer 34 is used to append one electrode of the electrically conductive connection device to the power substrate using liquid metal interface layers 35 and 36. Since these interfaces are not in contact with the semiconductor device and most extreme temperature swings, these interfaces can be substituted with traditional solid interconnects or conductive adhesive without large impact on device lifetime.

Electrically conductive solid metal spacers can also be used on the semiconductor device electrodes.

In the case that a solid metal spacer is not desired, the electrically conductive connection device can be made to be flexible by reducing the thickness of the conductive layers, for example to below 100 μm. Nevertheless, in power applications where currents of several hundred amps can be expected, these conductive layer thicknesses can be impractical to conduct the required current. Thicker conductive layers can be used.

The electrically conductive connection device can also be selectively coated on both the dielectric and conductive layers to enhance adhesive force and wettability in the contact areas in comparison to non-contact areas.

FIG. 12B shows the electrically conductive connection device with vias 37 through the dielectric layer to connect the conductive layers. These vias can also be filled with liquid metal interface material or another electrically conductive filling or metal to enhance the current carrying capability of the vias. Due to the wetting properties of liquid metals, the liquid metal can, in some examples, ascend the vias and pump out onto the top conductive layer, away from the semiconductor device electrode. This will reduce the amount of liquid metal available at the semiconductor electrode interface and reduce the performance of the interface. As a result, the vias can be capped on one or both sides with a metallic layer or other suitable layer to prevent pump out to the topside conductive layer.

FIG. 13A shows an example device including a pressure device that presses the electrically conductive connection device, the semiconductor device, the power substrate, and the electrically conductive spacer in the direction of the baseplate. In this example, the pressure device is the power terminals 40 which press directly to the electrically conductive connection device. Alternatively, they can press directly to the power substrate.

The power terminals 40 can take the form of sheet metal, spring contacts, pogo pins, or other suitable electrically conductive pressure terminal. The power terminals 40 can extend from the encapsulation material 41. Pressure can be applied by affixing the power terminals to the baseplate or the device housing which can be affixed to the baseplate (not shown).

The applied pressure can reduce the liquid interface material bondline thickness on the electrodes of the semiconductor device and solid metal spacer. In addition, if a flexible power substrate is used and pressure is applied directly to the semiconductor device, the liquid metal interface bondline between the power substrate and baseplate can be reduced in the area of highest power dissipation.

FIG. 13B shows an example where the power terminals 40 are acting as a pressure device and are appended to the electrically conductive connection device using a liquid metal interface 42. Pressure contacts in power devices can require pressures of over 1 MPa to reduce the electrical contact resistance to accommodate high currents. The use of liquid metal interface 42 reduces the electrical contact resistance and can enable use of a lower pressure.

The power terminals 40 can also be appended to the power substrate through a liquid metal interface material, as in other examples.

FIG. 13C and FIG. 13D show an example where the power terminals are used as a pressure device. A hollow electrically conductive solid metal sheet 44 encases an elastic material 46 and is sandwiched between the electrically conductive connection device and the power terminals. Liquid metal interfaces 43 and 45 append the power terminal and electrically conductive connection device to the sheet 44. The elastic material and sheet are compressible and can compensate for manufacturing tolerances if large and/or thick power terminals are used.

The pressure device examples described in FIG. 13A-FIG. 13D can all be appended to the power substrate, while non-electrically conductive elastic pressure devices can be used to press the electrically conductive pressure device, semiconductor device, conductive spacer, and power substrate in the direction of the baseplate. This device can comprise elastic or foam materials such as silicone rubber or foam.

In some examples, the power terminals are used as a pressure device. A soft or clastic material 46 is sandwiched between the electrically conductive connection device and the power terminals. Liquid metal interfaces 43 and 45 append the power terminal and electrically conductive connection device to soft or elastic material 46. The soft or clastic material 46 is compressible and can compensate for manufacturing tolerances if large and/or thick power terminals are used. The soft or elastic material 46 can, for example, comprise a compressible or soft metal like indium or graphite, an elastic material like foam or rubber, or a combination thereof.

The devices described herein can also be utilized without pressure devices.

FIG. 14A-FIG. 14C describes how to make a sub-component in the power module and this could also then be used in microelectronics and other substrates (e.g., glass substrates).

In some examples, the liquid metal can diffuse into the conductive layer, thereby forming a high melting intermetallic, which can form a rigid and solid bond between the insulating substrate and the conductive layer, rather than remaining liquid.

In some examples, this can be extended to multiple insulating layer and conductive layers to manufacture multi-layered substrates for planar transformers or substrates for power devices, PCBS, etc.

FIG. 14A shows a typical power substrate containing a dielectric layer 51, a topside conductive layer 52, and a bottom side conductive layer 53. Typically, the conductive layers are copper. The manufacturing process for prior art power substrates involves high temperatures. For example, the dielectric and copper layers can be heated up in a controlled oxygen environment to over 1000° C. and copper oxide used to bond the layers. This process temperature inhibits the feasibility of single sided power substrates. In addition, the thickness of the copper layers is limited, depending on the mechanical properties of the dielectric material. In some cases, the layers can be up to 200 μm-300 μm maximum.

FIG. 14B shows a power substrate with a dielectric layer 51, with a single topside conductive layer 52. Since liquid metal is able to wet a variety of dielectrics, such as glass, the layers are appended through a liquid metal interface material 54. This removes the bottom side conductive layer and improves the thermal resistance. In addition, the thickness of the top conductive layer 52 can be increased beyond 300 μm. The dielectric layer 51 material can also be chosen based on electrical and thermal properties rather than mechanical properties to survive a high temperature manufacturing process. This power substrate can be used in any of the examples of this devices described herein.

FIG. 14C shows an example where the liquid metal contact surfaces on the dielectric layer are selectively coated with a metallization 55 that enhances wetting and the adhesive force applied on the liquid metal. This layer can be a few μm in thickness and can easily be patterned on the dielectric layer without significant reliability concerns. Similar patterning can be performed on all liquid metal contact surfaces in the devices described herein.

FIG. 15A shows a typical semiconductor device with a number of topside electrodes 61. In power devices the topside electrodes are typically patterned using an aluminum based metallization with a thickness of several μm. As highlighted previously, aluminum provides poor wettability and adhesive force to the liquid metal. Additionally, it can be desired to use gallium based liquid metal materials or pastes on these electrodes, which reacts disadvantageously with aluminum. In some examples, coating the aluminum layer with an additional wettable metallization which also prevents contact between the liquid metal and aluminum is sufficient. This can be, for example, NiAg, NiPdAu, NiAu, or another metallization. The liquid metal materials in this case, however, will be limited to non-gallium based liquid metals, since, even with a coating, there exists regions around the edge of the electrode pads where gallium is able to contact the aluminum and the device can be destroyed.

To use gallium, all aluminum metal from the device can be completely removed. The aluminum can be replaced with another metal such as copper. Copper topside electrode metallization is sometimes already performed in some semiconductor devices.

FIG. 15B shows a semiconductor device with the aluminum electrode metallization removed 62. This can be performed using an aluminum etchant, or the device can be removed from the manufacturing process before the aluminum metallization is deposited.

In this case, the semiconductor electrodes are coated with only a diffusion barrier layer that can be in the region of nm thickness. A topside electrode metallization is used to join each individual semiconductor cell in parallel. The aluminum electrode metallization is therefore entirely replaced with a liquid metal interface layer. The liquid metal interface material directly wets the diffusion barrier layer.

FIG. 15C shows an alternative semiconductor device that can be used with a gallium based topside liquid metal interface material. In this case, the semiconductor electrodes 61 are surrounded by a barrier layer 63 that prevents the edges of the electrode from contact with the liquid metal.

FIG. 16 shows a flowchart for a manufacturing process for example devices described herein. Steps 4, 5, and 6 can be repeated as needed according to the number of liquid interfaces in the package and their melting temperatures. It is acknowledged that some steps can be removed, added, or performed in a different order in other examples.

In some examples, a vacuum step can be added to remove air pockets from the liquid metal interface materials, however voiding of liquid metal materials appears less of an issue than in traditional solder manufacturing processes.

### Example 6—LIME: Liquid Metal Packaging for Power Semiconductors

Abstract. State-of-the-art power semiconductors use solid metal interconnects such as wire-bonding, soldering, and sintering. Thermo-mechanical stress degrades solid metal interconnects and is the main cause of failure in power semiconductors. Herein, liquid metals, which are inherently resistant to thermo-mechanical stress, are used to replace solid metal interconnects. Preliminary results show that the use of liquid metals can increase the thermo-mechanical lifetime of power semiconductors by up to a factor of 40 to 60. Several iterations of liquid metal packages are shown, using both silicon and silicon carbide chips.

### 1 INTRODUCTION

1.1 Failure Modes in Power Packaging. Power semiconductors are one of the fundamental components in electrified transport, electricity generation/distribution, and industrial machinery. According to representatives from the wind, solar, air-craft, automotive, and grid industries, power semiconductors are the component for which reliability is most critical [1].

The dominant stressor on power semiconductors is thermo-mechanical, and the size, weight, and cost of power electronic systems is directly related to this stress. The most vulnerable components within a power semiconductor are the solid metal interconnects [2]. These are most commonly wire-bonding, soldering, or sintering based-solid metals that are physically welded together. Thermal cycling during operation leads to expansion and contraction of these materials and their eventual failure. Examples of thermo-mechanical failure in the top-side interconnects of power semiconductors are shown in FIG. 17. However, the same failure process is apparent in all interconnect layers. As a result, the semiconductor, and system components (such as capacitors, inductors, and cooling systems) must be oversized to ensure reliability.

A traditional silicon power device is packaged using solder (for die attach) and aluminum (Al) wire-bonding. However, for SiC devices, the material parameters which impact thermo-mechanical lifetime, such as Young's modulus, coefficient of thermal expansion, and Mohs hardness differ to that of silicon. This leads to SiC MOSFET power cycling lifetimes that may be just 20%-30% of Si IGBTs when packaged with identical interconnect technologies [3][4]. As a result, research in new packaging technologies for SiC devices is an area of interest [5].

Several advanced interconnects include copper (Cu) wire-bonding [6], Cu sintering [7], bond buffers [8], silver sintering [9], and Cu nanowires [10]. However, these technologies are vulnerable to the same inherent weakness as all solid metal interconnects (thermo-mechanical stress). In addition, some of these technologies require a higher temperature and higher-pressure manufacturing process, which may reduce yield and increase costs.

1.2 Liquid Metals. Liquid-metals (LMs) are inherently resistant to thermo-mechanical stress. “Liquid-metal” is a term generally used to describe metals that maintain liquid phase at a given temperature, for example at room temperature. Most often, the focus is on gallium (Ga) and Ga-based alloys for applications ranging from stretchable electronics, soft-sensors, robotics, drug delivery, and thermal interface materials [11].

Ga melts at 29.8° C., however it can be combined with other metals to form alloys with melting points down to 10° C. In addition, Ga experiences “super-cooling”, which means that Ga must usually be cooled to below its melting point to resolidify. The extent of this may reach −38° C., depending on the environmental conditions [12]. Nevertheless, operating at ambient temperatures down to −55° C. may be required in automotive, industrial, and military applications. As a result, solidification of Ga can be expected if used in these applications.

Furthermore, considering that the operating range of a power device reaches 200° C. (for wide-bandgap devices), the choice of metals that may enter their liquid-phase in this range could be increased. This would include indium (In), bismuth, and several other metallic alloys.

Therefore, the use of LMs in power semiconductor packaging will, most likely, require the ‘liquid’ interconnect to transition back and forth between the solid- and liquid-phase during normal operation. By transitioning from solid- to liquid-phase, either routinely during operation or using a predefined routine (i.e., periodically increasing the junction temperature to the melting point of the metal), an opportunity presents itself to manufacture a device with interconnects that can repair the degradation that forms in solid interconnects.

1.3 Summary. Discussed herein are several iterations of power semiconductors packaged using several types of LMs. A combination of both Ga- and In-based LMs are used. Results are provided from 200 V Si Diodes, a 600 V Si IGBTs, 600 V Si Diodes, and 1200 V SiC MOSFETs.

A focus herein is the thermal resistance (R_{TH}) and power cycling capability of these LM-based packages in comparison to traditional SAC305 solder and Al wirebond packaging. The Ga-based LMs remain in their liquid state for the entirety of the tests performed herein. However, the In-based alloys transition back and forth between solid and liquid.

Notable results are a 10% improvement in R_{TH} (junction-to-ambient) on 600 V Silicon diodes, and a factor of 40 to 60 increase in the power cycling lifetime of 1200 V SIC MOSFETs.

Nevertheless, it is found that the primary failure mechanism for LM packages is corrosion. Additionally, solutions for automated dispensing and manufacturing, as well as evaluating issues regarding intermetallic formation and optimal surface coatings in LM contact areas are considered.

### 2 LIQUID METAL PACKAGING

2.1 Prior Use of Liquid Metal in Electronics Packaging. LMs have primarily been considered for use in thermal interface materials and are now used in some commercial products such as ASUS ROG laptops and the Sony PlayStation 5. For use as electrical interconnects, investigations are more limited. Ga and In have an electrical conductivity that is approximately ⅛th and ⅕th of Cu and therefore may be overlooked for use as high current density interconnects.

In microelectronics, the use of Ga-based LM for flip-chip packaging and the use Ga-based nanoparticles for Land-Grid-Array packaging have been investigated [13, 14]. In both cases, a well/socket was used to house the LM.

In power electronics, the use of Ga-based LM for die-attach of a SiC MOSFET has been demonstrated [15]. In this case, a cavity is used in the Cu substrate and the chip floats in the LM. Elsewhere, a Ga-based LM has been used for the topside interconnect on a silicon diode [16]. Again, a cavity was used in the Cu plane to house the LM. Furthermore, the Al surface of the chip was coated with titanium to prevent reaction with Ga. An In-based LM has also been used to manufacture a press-pack Si IGBT [17].

Additionally, some patents on power devices exist, which again include methods for implementing cavities or encapsulation to constraint the LM [18][19].

On the other hand, LM interconnects are detailed herein that are contained through a combination of enhanced viscosity, surface tension, and capillary forces acting on the LM. Section 2.2 provides some additional data from the prototype found in [16], as well as a similar prototype on a silicon IGBT. These designs used barriers or recesses to contain LM, with limited results. However, Section 2.3 details two iterations using a Ga-based paste, which is constrained without the use of barriers or cavities [20].

### 2.2 Cavity-Based LM Designs

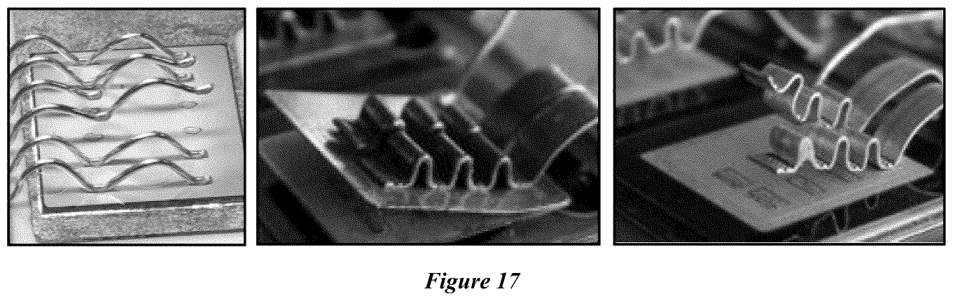

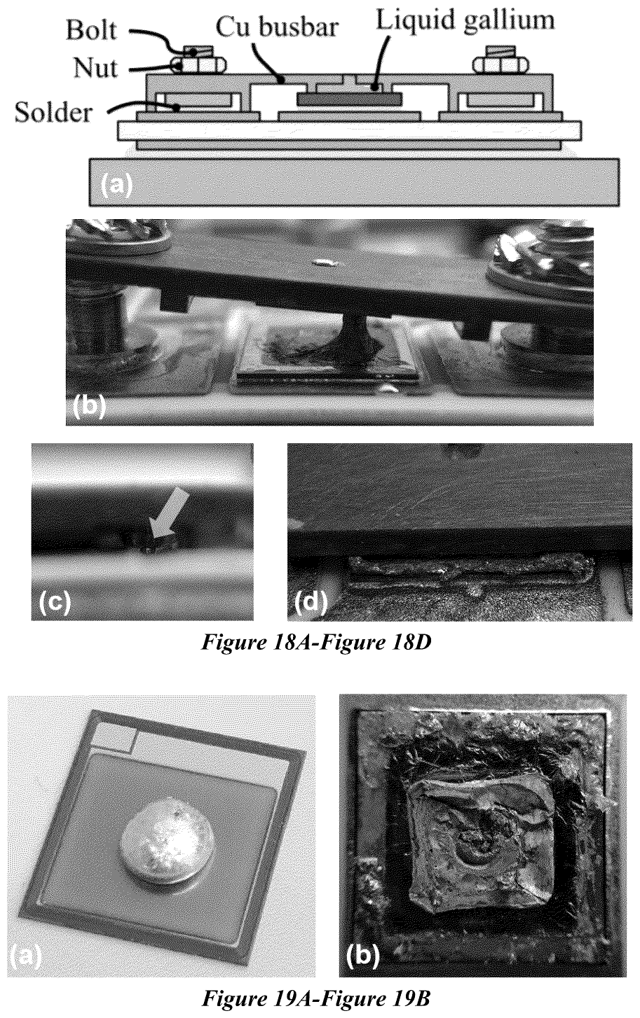

2.2.1 200 V Silicon Schottky Diode (LM-1). FIG. 18A-FIG. 18D shows a schematic and photos of an Si sch diode from packaged with Ga on the topside. SAC305 solder was used for die-attach and DBC to baseplate. The same Si diode, packaged with Al wirebonds, is shown in FIG. 17.

Since the topside of the diode is Al, a 100 nm-200 nm layer of titanium (Ti) was sputtered to prevent reaction of Ga and Al. While this barrier layer prevented reaction during assembly, it ruptured during operation and no longer prevented contact between Ga and Al. However, surprisingly, the diodes still appeared to operate normally for the purposes of a power cycling test. FIG. 19A-FIG. 19B shows Ga on a Ti barrier layer from LM-2 (Section 2.2.2), as well as the ruptured layer on LM-1 where reaction between Ga and Al can be observed.

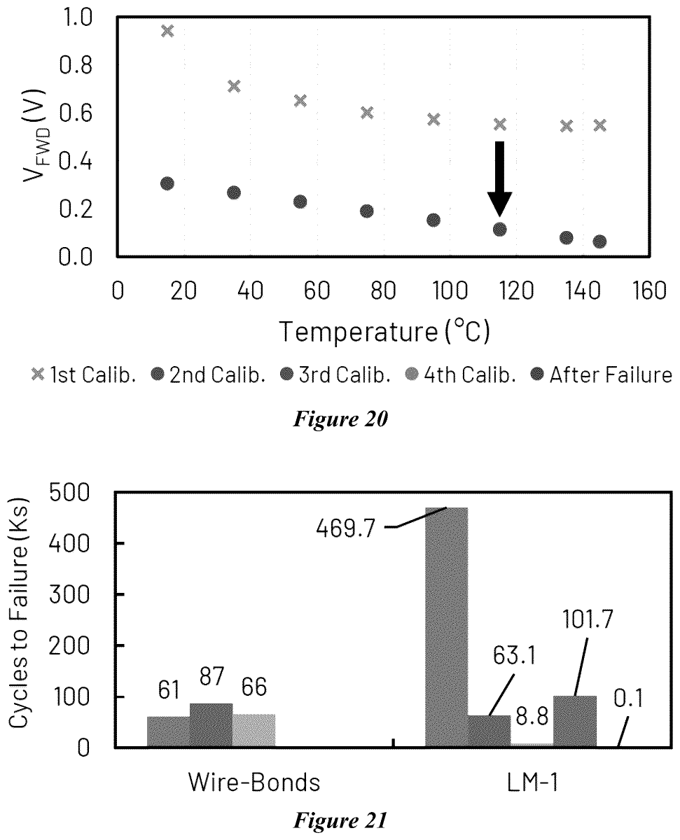

A key finding from LM-1 is found in FIG. 20. This shows calibration of V_{CE}(T) required for T_{J} measurement during power cycling. It was found that immediately after manufacture, the V_{FWD} of the diode was extremely high. After the first calibration routine was completed, returning to room-temperature and repeating the calibration routine showed a drop in V_{FWD}. After this, stabilization of the V_{FWD} occurred and was consistent with the V_{FWD} measured on wirebonded diodes. A hypothesis for this is inadequate wetting of the contact interfaces by the Ga LM. Therefore, in Section 2.3 a pre-aging process for LM interfaces is employed during manufacture.

A total of five LM-1 samples were manufactured, along with three Al wirebonded diodes (two with 250 μm diameter wirebonds, and one with 350 μm diameter wirebonds).

The samples were power cycled using a constant current of 200 A and on/off-times of 2 seconds. The induced ΔT_{J} was between 70° C. to 80° C. FIG. 21 displays the number of cycles to failure. For Al wirebonded diodes, all samples failed between 61k to 87k cycles. For LM-1, two diodes failed almost instantly, while one diode survived 470k cycles.

The failure modes of LM-1 were corrosion (FIG. 18D), as well as leakage of the Ga which short circuited the diode (FIG. 18C). In fact, the recess in the busbar above the chip appeared to offer little benefit in containment of the LM.

2.2.2 600 V Silicon IGBT (LM-2). FIG. 22A-FIG. 22C show photos of a Si IGBT with Ga LM for the topside. Changes to LM-1 were the inclusion of a “guard ring” with a height of 1 mm on the IGBT surface, the use of silicone potting gel, and an Al wirebond to the gate pad. The thick Cu busbar, therefore, was intended to “float” in the recess created by the guard ring.

Once more, a barrier layer was used to prevent reaction of Ga and Al (FIG. 19A), which was ineffective at preventing reaction during operation. FIG. 22B and FIG. 22C show corrosion of the package after power cycling. FIG. 22B shows the corrosion extending to the bondwire used for the kelvin-emitter contact. Interestingly, the corrosion did not consume the gate pad in either image. The guard ring and silicone gel were also ineffective at containing the Ga LM. Furthermore, it was observed that the Ga can escape over the top of the guard ring (FIG. 22C).

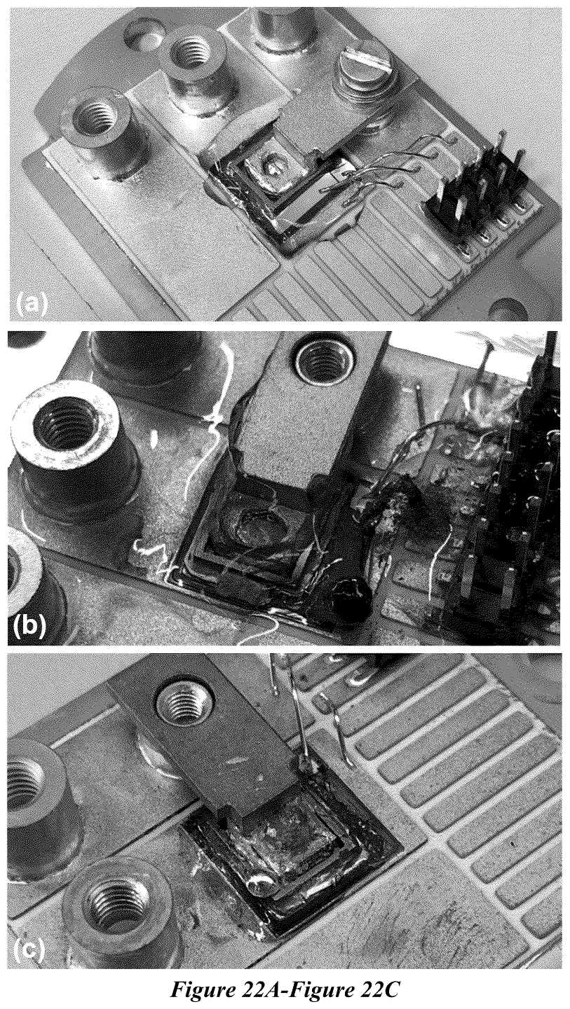

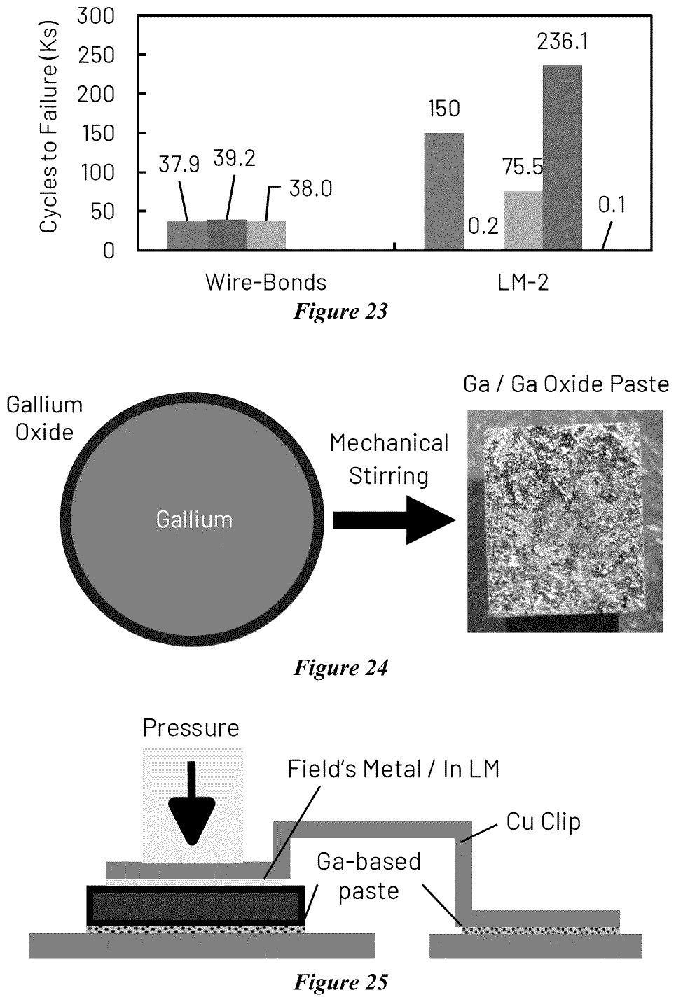

Five samples of LM-2 were power cycled using on/off-times of 2-seconds. The induced ΔT_{J} was between 105° C. and 115° C. FIG. 23 displays the results. The three wirebonded IGBTs (all bonded with 350 μm) wire survived approximately 39k cycles. For LM-2, two samples failed almost instantly, and the best performing sample survived 236k cycles.

2.3 LIME Packaging. While LM-1 and LM-2 showed potential improvements in the power cycling lifetime, low yield, leakage of Ga, and corrosion of Ga/Al were clear issues. The next section discusses LM-based packages using a combination of Ga-based pastes and In-based LMs. Superior results were observed, and these packages will now be denoted using the acronym “LIME”.

2.3.1 Liquid Metal Pastes. LIME uses a paste containing particles of Ga oxide. The manufacturing process is detailed in and can be performed in air. The basic principle is outlined in FIG. 24. Ga forms a thin and brittle layer of the solid, Ga oxide, on exposure to oxygen. Mechanical stirring of Ga breaks this oxide layer and exposes more Ga to the atmosphere. Therefore, continuous stirring gradually increases the content of Ga oxide in the liquid. This produces a paste like material with differing mechanical properties, such as increased viscosity and more predictable spreading. The thermal conductivity is also lower than the pure Ga LM, and is dependent on the mixing time. Other solid particles could be added to further alter material properties.

Herein, a Ga-based paste is used for die-attach, while In-based LMs are used for topside. These range from Field's metal (melting point of 62° C.) to In-silver alloys (melting point of around 142° C.). A 600 V Si Diode is described in Section 2.3.3, and a 1200 V SiC MOSFET is described in Section 2.3.4.

2.3.2 General Structure and Manufacturing Process. The general structure of LIME packages is shown in FIG. 25. The LM materials are used as interfaces at contact areas of a Cu clip, chip, and Cu substrate. In-based LMs are used on the topside of the chip to avoid reaction between Al and Ga.

Additionally, a silicone rubber pressure device is used to press the chip into the substrate. Since the Ga-based pastes have a thermal conductivity 50% less than solder (and an order of magnitude less than some silver sinter pastes) [21], it is important to minimize the bondline thickness.

Minimizing the bondline thickness has an additional benefit of helping with containment of the LM materials. LIME uses only the viscosity, surface tension, and capillary forces acting on the LM for containment. This is distinct compared to prior literature and the designs presented in Section 2.2, which generally use some form of well, cavity, or encapsulation for containment.

Given the results from Section 2.2, which show unstable electrical performance of LM contacts immediately after manufacture, a pre-aging process of LM contact interfaces was implemented.

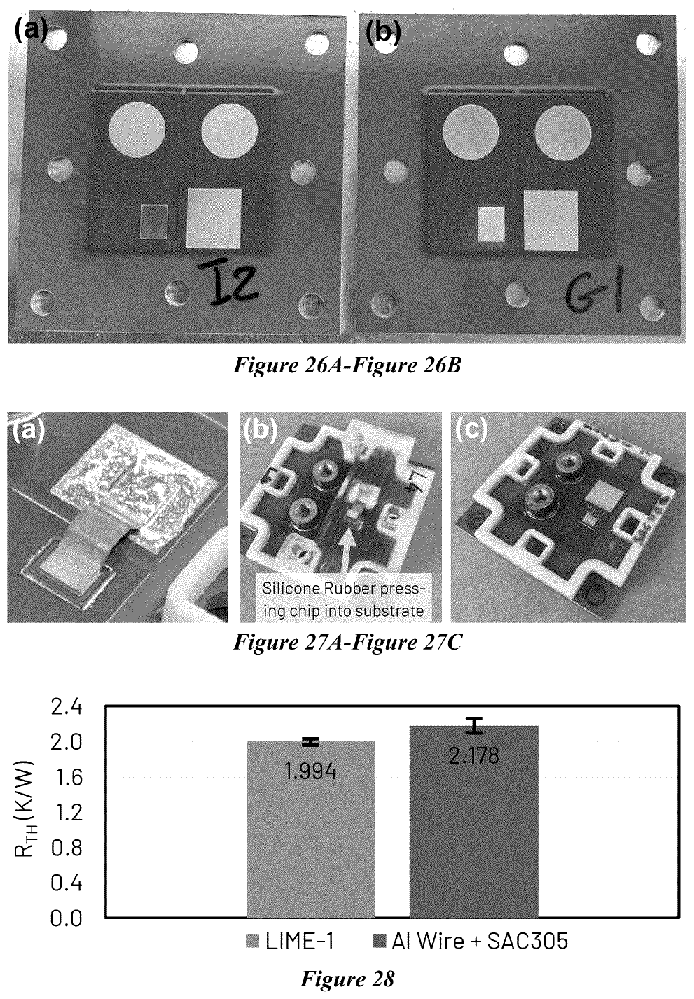

FIG. 26A-FIG. 26B shows the Cu pads from an aluminum clad PCB after being coated with LM (Ga and Field's metal) and heated on a hotplate at 180° C. for 12 hours. Excess LM has been removed in these photos, and clear formation of both an In—Cu and Ga—Cu intermetallic can be viewed. After this, LM materials were reapplied and the packages assembled. After implementing this process, it was found that the initial electrical instability was reduced, and no immediate failures were experienced.

2.3.3 600 V Si Diode (LIME-1). FIG. 27A-FIG. 27C shows a 600 V Si Diode with a Ga-based paste and Field's metal for the topside interconnect. The silicone rubber pressure device is housed in a transparent lid and shown in FIG. 27B. The solder mask on the aluminum clad PCB is primarily used for chip alignment, since the entire manufacturing process is performed manually.

For comparison, a set of Si diodes were also manufactured using SAC305 solder and 8×250 μm Al wirebonds (FIG. 27C).

The R_{TH} was measured at 24 A with a heating and cooling period of 30-seconds. A Siemens Micred PowerTester 2400A was used, and junction temperature was measured using a sensing current of 50 mA. FIG. 28 displays the results from six samples of each group of diodes. The mean R_{TH} of LIME-1 diodes shows a 9% improvement. In addition, LIME-1 shows a standard deviation of 0.022 K/W compared to 0.043 K/W.

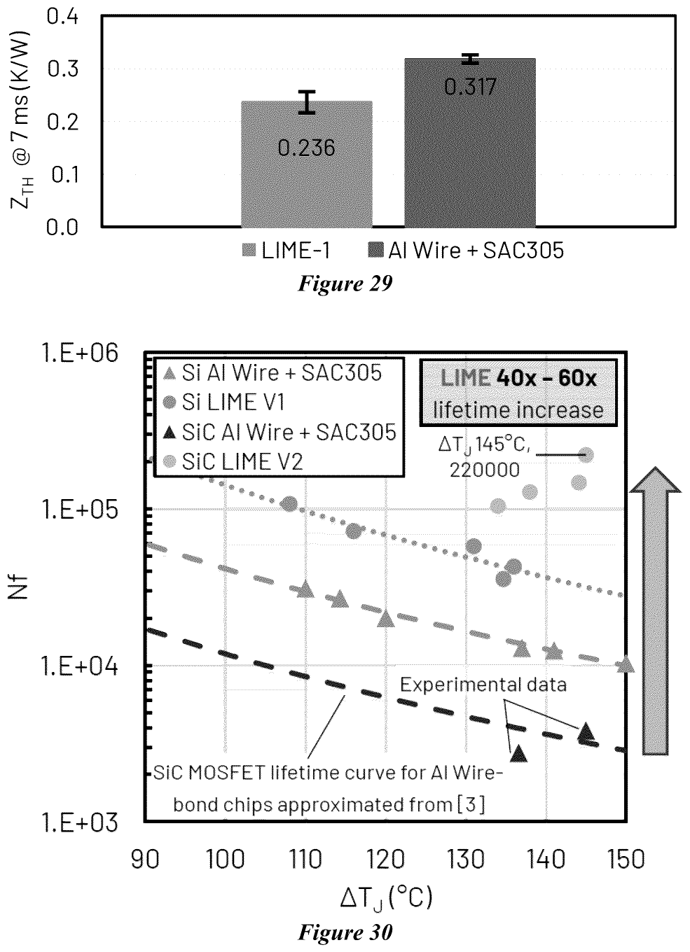

It should be noted, however, that another study performed on the same Al wirebonded packages showed that the overall R_{TH} was largely unrelated to voids in the solder layer [22]. Therefore, the time-dependent Z_{TH} at 7-milliseconds after turn-off is shown in FIG. 29. This time-constant was shown to have a much higher correlation to the quality of the die-attach [22]. LIME-1 has a 25% improvement. However, the standard deviation was higher at 0.02 K/W vs. 0.008 K/W.

Power cycling was performed with on- and off-periods of 1-second and results are displayed in FIG. 30. Cycling currents ranged from 23 A to 28 A, giving a range of ΔT_{J} from 108° C. to 151° C. All samples were cycled with constant current, and the failure criteria was either +5% V_{FWD} or +15% ΔT_{J}. LIME-1 packaged diodes were observed to have a lifetime 3.3× higher than SAC305 and Al wirebonded diodes.

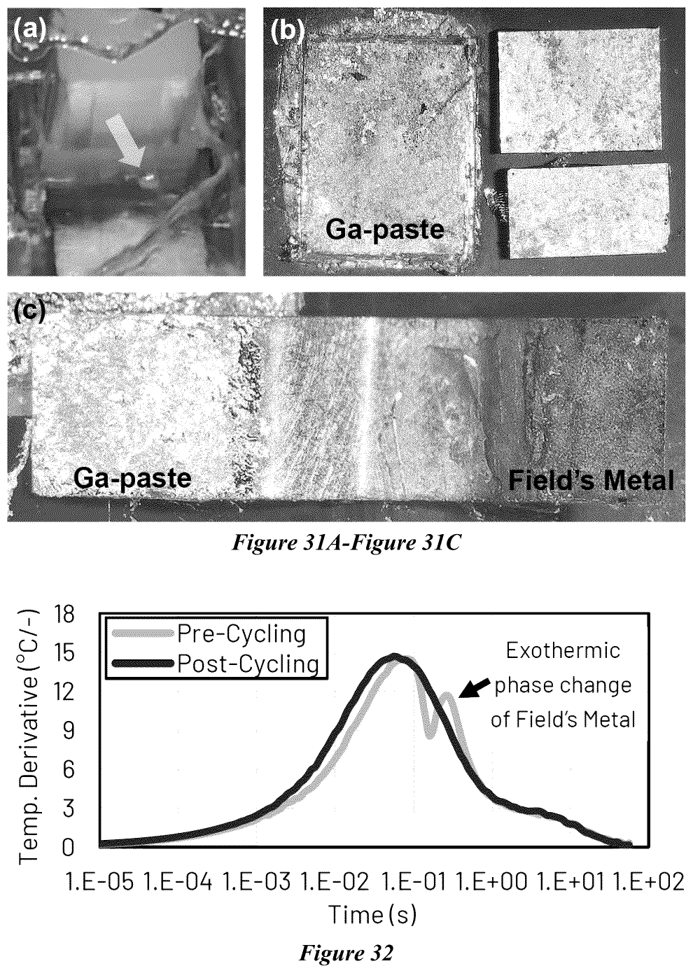

All wirebonded diodes failed from a 15% increase in ΔT_{J}, while LIME-1 diodes failed from a combination of +5% V_{FWD} and +15% ΔT_{J}. This was likely due to both pump-out and corrosion of Field's metal. To provide evidence for this, FIG. 31A shows an image from a video taken during power cycling [23]. This shows that Field's metal was able to migrate to the topside of the Cu clip—against gravity and away from the chip surface.

It is hypothesized that the cause of the pump-out is that Cu (and the Cu—In intermetallic) provides a larger adhesive force on the Field's metal than the Al chip surface. Therefore, containment of LMs is dependent on capillary forces at the contact and surrounding interfaces.

FIG. 31B and FIG. 31C show images of the LM interfaces at the end-of-life. From visual inspection, the amount of LM present at each interface had decreased. For the die-attach with the Ga-based paste (which should remain liquid at room temperature), force had to be used such that the chip cracked upon separation. This indicates that the pre-aging process of the Cu metal did not saturate the Cu such that intermetallic formation was stabilized. Alternatively, use of other (more favorable) surface metals such as NiAu may be required instead [24].

The Ga paste interface between the Cu clip and the Cu pad, however, remained liquid. This interface, nevertheless, was not exposed to the high temperatures of the chip.

Regarding the Field's metal interface on the Cu clip, clear corrosion can be observed, and no LM remained. Further evidence for this can be observed in post-power cycling R_{TH} measurements shown in FIG. 32. This figure displays the cooling rate over time. Since Field's metal melts at 62° C., it transitions from liquid-to-solid during the cooling of an R_{TH} measurement. This is an exothermic process, which releases heat- and therefore momentarily slows the cooling rate of the device. In pre-power cycling measurements, this transition can clearly be seen. However, it is not present in the post-power cycling measurement.

Further images and results for LIME-1 can be found in [25].

2.3.4 1200 V SIC MOSFET (LIME-2). LIME-2 was assessed on a SiC MOSFET. Although the general structure of the package was identical to LIME-1, there were notable differences in the surface metals at the LM contact interfaces. Firstly, the topside Al metallization on the power source pads were coated with Ti/Ni/Ag. Secondly, a DBC based design was used—with the Cu surface coated with Ni/Au. The Cu clip was also coated with Ag.

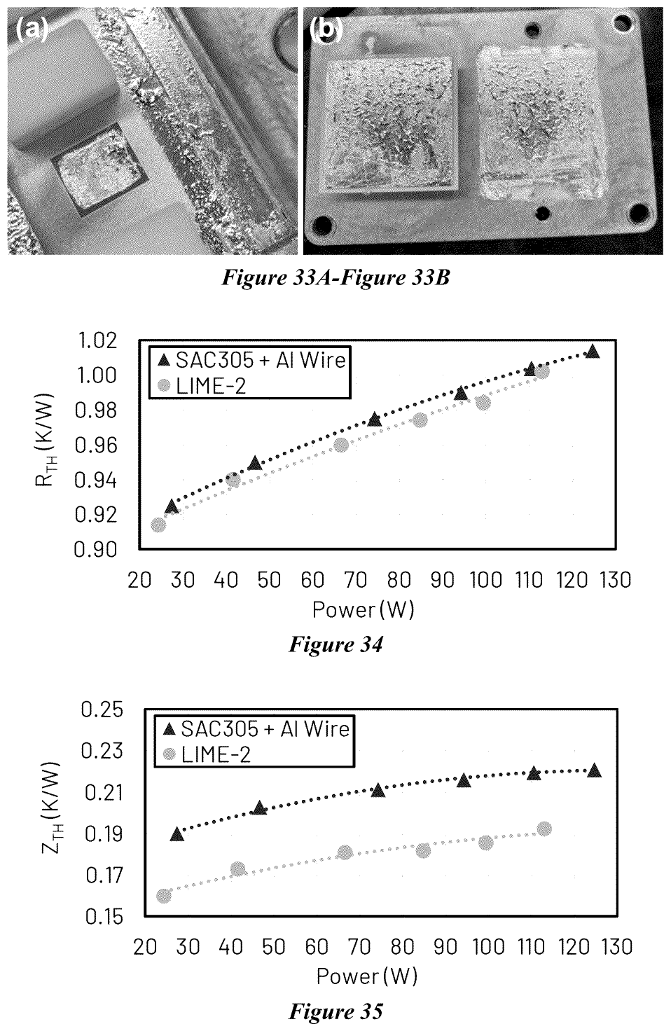

Finally, all interfaces in the package were replaced with an LM. This includes the die-attach, chip top-side, DBC-to-baseplate, and power terminals to DBC. The gate pad remained metallized with Al, and therefore the gate connection was made using a pogo-pin. FIG. 33A-FIG. 33B shows images of LM replacing the baseplate to DBC solder, die-attach, and power terminal to DBC. Solder mask can again be seen, which was used for chip alignment to enable use of a Silicone rubber pressure device.

FIG. 34 and FIG. 35 shows the R_{TH} and Z_{TH} (at 7-milliseconds) from one sample, respectively. Measurements are displayed with respect to power dissipation [26, 27]. The R_{TH} shows a 1% difference between LIME-2 and the SAC305 packaged SiC MOSFET. However, for Z_{TH} at 7-milliseconds, LIME-2 shows an improvement of approximately 13% across power dissipation.

Power cycling results are displayed in FIG. 30. A total of four LIME-2 and two SAC305 and Al wirebond SiC MOSFETs were tested at a ΔT_{J} from 135° C. to 145° C. LIME-2 survived between 103,000 to 220,000 cycles. Al wirebonded samples survived between 2,800 to 3,800 cycles. This represents a lifetime increase by a factor of 40 to 60.

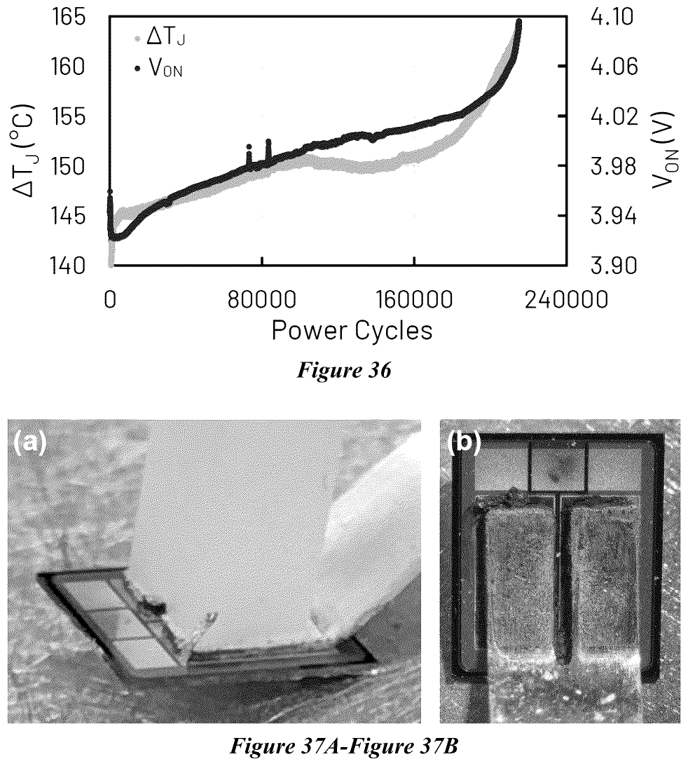

There appeared to be no clear correlation with ΔT_{J}, however multiple indium-based alloys were used across the four samples, which included Field's metal, In—Sn, and In—Ag. The longest surviving sample used an In—Sn alloy, and the Vox and ΔT_{J} evolution throughout the power cycling test is shown in FIG. 36. With the small sample size and the variability in depositing the LM (due to manual processing), no conclusions can be drawn on which material is most suitable in this application.

The failure mechanism again appeared to be corrosion of the topside In LM interface. FIG. 37A-FIG. 37B shows growth of a whisker from the chip surface, as well as corrosive product between the Cu clip and chip. In addition, the Ag coating on the Cu clip shows discoloration.

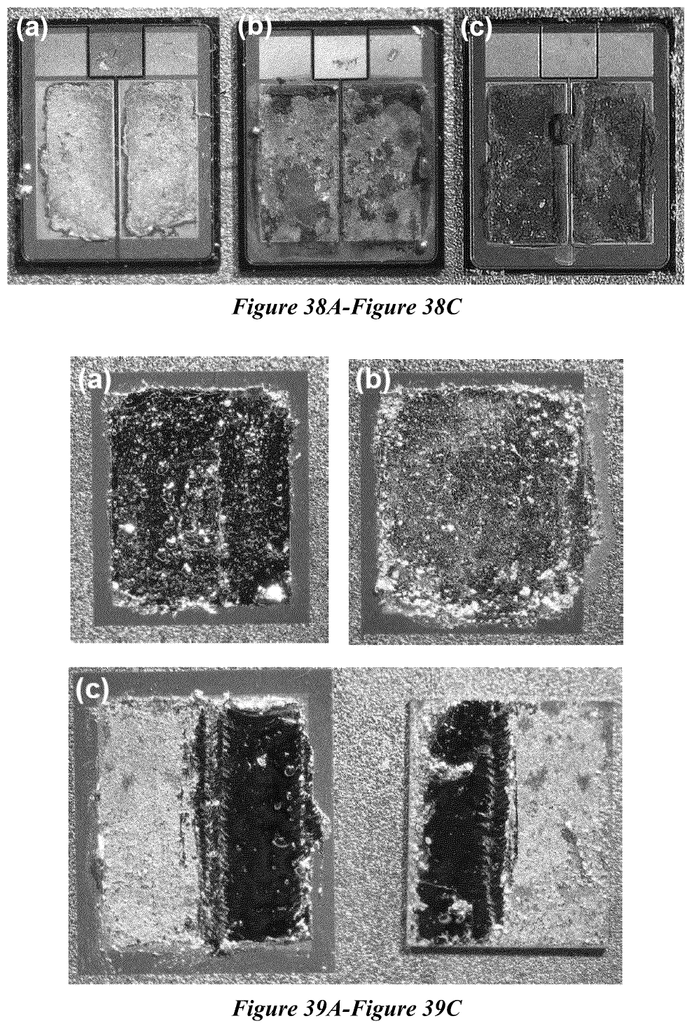

A notable advantage of LM-based packaging is that it enables easy separation of parts for visual inspection. This was used to generate FIG. 38A-FIG. 38C, which documents the progression of degradation of the In interface. This figure shows images from two SiC MOSFETs which were prematurely removed from power cycling. SiC MOSFETs separated at 10k, 60k, and 147k power cycles are shown. Additional research can further characterize the degradation process; however, a preliminary hypothesis is that the corrosion product is an insulating compound that (a) is no longer liquid during operation of the device, and (b) gradually increases the resistance of the interconnect as more of the Indium is consumed.

Images of the Ga-paste die-attach are shown in FIG. 39A-FIG. 39C. All chips were easily separated upon completion of power cycling-unlike in LIME-1 (FIG. 31B). Post-power cycling images show a clear change in the material. This degradation is most likely in accordance with prior research on Ga-based materials in high humidity conditions [28]. However, scratching the surface of the interfaces with a tweezer revealed that a considerable amount of LM remained. Therefore, it is assumed that the end-of-life for the die-attach interface has not been reached.

### 3 CONCLUSION

Herein, liquid metal interfaces were used to package power semiconductors. A combination of gallium and indium based liquid metal materials were used, with only capillary forces required for containment. These materials are, in theory, immune to thermo-mechanical stress.

On SiC MOSFETs, the thermo-mechanical lifetime (assessed through power cycling) was increased by a factor of 40 to 60 in comparison to standard SAC305 solder and aluminum wirebonds.

However, corrosion was found to be the primary failure mechanism, particularly for indium based liquid metal interfaces.

### REFERENCES

[1] J. Falck et al. “Reliability of Power Electronic Systems: An Industry Perspective,” in IEEE Industrial Electronics Magazine, vol. 12, no. 2, pp. 24-35, June 2018, doi: 10.1109/MIE.2018.2825481.
[2] M. Ciappa, “Selected failure mechanisms of modern power modules”, Microelectron. Reliab., vol. 42, no. 4, pp. 653-667, 2002, doi: https://doi.org/10.1016/S0026-2714 (02) 00042-2.
[3] F. Hoffmann et al. “Comparison of the Power Cycling Performance of Silicon and Silicon Carbide Power Devices in a Baseplate Less Module Package at Different Temperature Swings,” 2021 33rd International Symposium on Power Semiconductor Devices and ICs (ISPSD), Nagoya, Japan, 2021, pp. 175-178, doi: 10.23919/ISPSD50666.2021.9452242.
[4] N. Baker et al., “Power Cycling of 1.7 kV Multi-Chip Power Modules-SiC MOSFETs vs Silicon IGBTs,” PCIM Europe 2024; International Exhibition and Conference for Power Electronics, Intelligent Motion, Renewable Energy and Energy Management, Nürnberg, Germany, 2024, pp. 1918-1924, doi: 10.30420/566262269.
[5] L. Wang et al. “Review of Topside Interconnections for Wide Bandgap Power Semiconductor Packaging,” in IEEE Transactions on Power Electronics, vol. 38, no. 1, pp. 472-490, January 2023, doi: 10.1109/TPEL.2022.3200469.
[6] Emre Özkol et al. “Improving the power cycling performance of IGBT modules by plating the emitter contact,” Microelectronics Reliability, Volume 55, Issues 3-4, 2015, Pages 552-557, ISSN 0026-2714, https://doi.org/10.1016/j.micro-rel.2015.01.001.
[7] J. Kahler et al. “Sintering of Copper Particles for Die Attach,” in IEEE Transactions on Components, Packaging and Manufacturing Technology, vol. 2, no. 10, pp. 1587-1591 October 2012, doi: 10.1109/TCPMT.2012.2201940.
[8] Streibel et al., “Reliability of SiC MOSFET with Danfoss Bond Buffer Technology in Automotive Traction Power Modules,” PCIM Europe 2019; International Exhibition and Conference for Power Electronics, Intelligent Motion, Renewable Energy and Energy Management, Nuremberg, Germany, 2019, pp. 1-7.
[9] T. Stockmeier et al. “SKIN: Double side sintering technology for new packages,” 2011 IEEE 23rd International Symposium on Power Semiconductor Devices and ICs, San Diego, CA, USA, 2011, pp. 324-327, doi: 10.1109/ISPSD.2011.5890856.
[10] Z. Yu et al., “Cu—Cu Thermocompression Bonding with Cu-Nanowire Films for Power Semiconductor Die-Attach on DBC Substrates,” 2021 IEEE 23rd Electronics Packaging Technology Conference (EPTC), Singapore, Singapore, 2021, pp. 1-7, doi: 10.1109/EPTC53413.2021.9663890.
[11] S. Tang et al. “Gallium Liquid Metal: The Devil's Elixir,” Annual Review of Materials Research, Volume 51, pp. 381-408, 2021, doi: https://doi.org/10.1146/annurev-matsci-080819-125403.
[12] Ishan D. Joshipura et al. “An atomically smooth container: Can the native oxide promote super-cooling of liquid gallium?,” iScience, Volume 26, Issue 4, 2023, https://doi.org/10.1016/j.isci.2023.106493.
[13] P. Ralston et al. “Liquid-Metal Vertical Interconnects for Flip Chip Assembly of GaAs C-Band Power Amplifiers Onto Micro-Rectangular Coaxial Transmission Lines,” in IEEE Journal of Solid-State Circuits, vol. 47, no. 10, pp. 2327-2334 October 2012, doi: 10.1109/JSSC.2012.2204930.
[14] K. Meyyappan et al., “Liquid Metal Based Low Resistance Interconnect Technology,” in IEEE Transactions on Components, Packaging and Manufacturing Technology, vol. 13, no. 4, pp. 465-471, April 2023, doi: 10.1109/TCPMT.2023.3274743.
[15] W. Mu et al. “Liquid Metal Fluidic Connection and Floating Die Structure for Ultralow Thermomechanical Stress of SiC Power Electronics Packaging,” in IEEE Transactions on Power Electronics, vol. 39, no. 7, pp. 7808-7814 July 2024, doi: 10.1109/TPEL.2024.3379121.
[16] Z. Sun et al., “Thermal Characteristics of Liquid Metal Interconnects for Power Semiconductors,” 2023 IEEE Applied Power Electronics Conference and Exposition (APEC), Orlando, FL, USA, 2023, pp. 1135-1140, doi: 10.1109/APEC43580.2023.10131435.
[17] X. Wang et al., “Thermal Contact Resistance Optimization of Press-Pack IGBT Device Based on Liquid Metal Thermal Interface Material,” in IEEE Transactions on Power Electronics, vol. 37, no. 5, pp. 5411-5421 May 2022, doi: 10.1109/TPEL.2021.3129846.
[18] A. Lostetter, “Apparatus having self healing liquid phase power connects and method thereof,” U.S. Pat. No. 9,728,868B1, Feb. 10, 2014.
[19] D. Paresh Parekh et al., “Semiconductor package with liquid metal conductors,” U.S. Pat. No. 10,879,151B2, Dec. 28, 2018.
[20] N. Baker, “LIQUID METAL INTERCONNECTS FOR POWER SEMICONDUCTOR MODULES,” U.S. Patent Application 63/657,159.
[21] W. Kong et al. “Oxide-mediated mechanisms of gallium foam generation and stabilization during shear mixing in air,” Soft Matter, vol. 16, no. 25, pp. 5801-5805, 2020.
[22] N. Carlson et al. “Solder Void Impact on Power Device Thermal Impedance Using Transient Thermal Analysis,” International Workshop on Integrated Power Packaging 2025, Tuscaloosa, Alabama, USA, April 2025.
[23] https://www.youtube.com/shorts/wauVAXqpS7E
[24] Meyyappan, K. et al. (2023), Field Risk Evaluation of Liquid Metal Interconnects in Microelectronics Applications. Adv. Eng. Mater., 25:2300880. https://doi.org/10.1002/adem.202300880.
[25] N. Baker et al. “Liquid Paste Interconnects on a Silicon Power Diode,” IEEE Transactions on Components, Packaging and Manufacturing Technology, under review.
[26] Baker, Nick, Impact of Operating Mode on Chip Temperature Imbalance in Multi-Chip Sic Mosfet Power Modules. Available at SSRN: https://ssrn.com/abstract=5146705 or http://dx.doi.org/10.2139/ssrn.5146705
[27] Nick Baker et al. “Multi-Chip Temperature Imbalance of SiC MOSFETs in MOSFET vs. Body-Diode Conduction” International Workshop on Integrated Power Packaging 2025, Tuscaloosa, Alabama, USA, April 2025.
[28] Meyyappan, K. et al. (2024), Gallium-Based Liquid-Metal Alloys: Challenges and Risk Management in High-Humidity Environments. Adv. Eng. Mater., 26:2400399. https://doi.org/10.1002/adem.202400399

### EXEMPLARY ASPECTS

In view of the described compositions, devices, systems, and methods, herein below are described certain more particularly described aspects of the inventions. The particularly recited aspects should not, however, be interpreted to have any limiting effect on any different claims containing different or more general teachings described herein or that the “particular” aspects are somehow limited in some way other than the inherent meanings of the language and formulas literally used therein.

Example 1: A semiconductor package device, comprising: a semiconductor device comprising an electrode and/or contact pad; a solid metal circuit element; and a liquid metal interface comprising a liquid metal material; wherein the liquid interface appends at least a portion of the solid metal circuit element to at least a portion of the electrode and/or contact pad within a contact area; wherein adhesive forces, cohesive forces, surface tension forces, capillary forces, viscosity, and/or wetting characteristics enable containment of the liquid metal interface within the contact area.

Example 2: The device of any example(s) herein, particularly example 1, wherein the liquid metal material comprises an alloy comprising gallium, indium, tin, bismuth, or a combination thereof.

Example 3: The device of any example(s) herein, particularly examples 1-2, wherein the liquid metal material comprises a room temperature liquid metal material, a low temperature liquid metal material, or a combination thereof.

Example 4: The device of any example(s) herein, particularly examples 1-3, wherein the device comprises a first liquid metal interface comprising a first liquid metal material and a second liquid metal interface comprising a second liquid metal material.

Example 5: The device of any example(s) herein, particularly example 4, wherein the first liquid metal material transitions between liquid and solid at a first temperature, and the second liquid metal material is transitions between liquid and solid at second temperature, the first temperature being different than the second temperature.

Example 6: The device of any example(s) herein, particularly examples 1-5, wherein the liquid metal interface has a thickness of 25 μm or less.

Example 7: The device of any example(s) herein, particularly examples 1-6, wherein the liquid metal interface has a thickness of 10 micrometers or less.

Example 8: The device of any example(s) herein, particularly examples 1-7, wherein the liquid metal interface has a thickness and/or composition that varies.

Example 9: The device of any example(s) herein, particularly examples 1-8, wherein the liquid metal material further comprises filler particles, such that the liquid metal material resembles a paste or foam.

Example 10: The device of any example(s) herein, particularly example 9, wherein the liquid metal material comprises a Ga-based paste.

Example 11: The device of any example(s) herein, particularly examples 1-10, wherein the liquid metal material comprises Ga and an additional metal such as palladium platinum, gold, silver, or a combination thereof.

Example 12: The device of any example(s) herein, particularly examples 1-11, wherein the portion of the semiconductor device and solid metal circuit element contacting the liquid metal interface are further coated with a metallization layer that enhances liquid metal wetting, enhances the adhesive force applied to the liquid metal interface material, prevents absorption of the liquid metal into the surface, or a combination thereof.

Example 13: The device of any example(s) herein, particularly example 12, wherein the metallization layer comprises gold, silver, tantalum, titanium, platinum, palladium, nickel, or a combination thereof.

Example 14: The device of any example(s) herein, particularly examples 12-13, wherein at least a portion of the semiconductor device and solid metal circuit element are not in contact with the liquid metal interface, said portion of the semiconductor device and solid metal circuit element not contacting the liquid metal interface have a surface treatment or coating that reduces the adhesive force and wettability of the liquid metal interface material therewith.

Example 15: The device of any example(s) herein, particularly examples 1-14, further comprising a lead frame and an electrically conductive connection device, where a first liquid metal interface appends at least a portion of the semiconductor device to at least a portion of the electrically conductive connection device, and where a second liquid metal interface appends at least a portion of the semiconductor device to at least a portion of the lead frame.

Example 16: The device of any example(s) herein, particularly examples 1-15, further comprising an encapsulation material that encapsulates at least a portion of the semiconductor device and liquid metal interface.

Example 17: The device of any example(s) herein, particularly examples 1-16, further comprising a pressure device configured to apply a pressure to at least a portion of the device.

Example 18: A method of making the device of any example(s) herein, particularly examples 1-17.

Example 19: The method of any example(s) herein, particularly example 18, wherein the method comprises, in the following order: pre-wetting liquid metal interface contact areas with liquid metal, aging the liquid metal contact areas to induce intermetallic formation prior to assembly, re-wetting at least one liquid metal contact area, and joining at least one liquid metal contact area.

Example 20: The method of any example(s) herein, particularly examples 18-19, wherein the liquid metal contact areas are wetted and joined in order of highest melting temperature first.

Example 21: A liquid interface semiconductor package, comprising:
at least one semiconductor device,
at least one power substrate with a dielectric layer,
at least one planar structured electrically conductive connection device with at least one dielectric layer, at least one solid metal conductive layer, and at least one electrode,
at least one power terminal,
a baseplate,
a package housing,
a room temperature liquid metal interface material that appends at least one electrode of the semiconductor device to the power substrate,
a low, above room temperature, liquid metal interface material that appends at least one electrode of the semiconductor device to at least one electrode of at least one electrically conductive connection device, with the above room temperature liquid metal interface being transitioned to liquid state by the normal operating power losses and temperature fluctuations of the semiconductor device,
a solid metal electrically conductive spacer that is coupled to the power substrate and at least one electrode of an electrically conductive connection device through liquid metal interface materials,
a liquid metal interface material that appends at least one power substrate to the baseplate
at least one pressure device that is designed to press the electrically conductive connection devices, the semiconductor devices, the power substrates, and the electrically conductive spacers, in the direction of the baseplate and minimizing the thickness of the liquid metal interface materials,
an encapsulation material that encapsulates the semiconductor devices, and liquid metal interfaces.

Example 22. The apparatus of any example herein, particularly example 21, where the liquid metal interfaces are below 20 μm in thickness.

Example 23. The apparatus of any example herein, particularly example 21, where the electrically conductive connection device is a solid metal conductor.

Example 24. The apparatus of any example herein, particularly example 21, where the electrically conductive connection device is non-planar and can be attached to a power substrate without the use of electrically conductive spacers.

Example 25. The apparatus of any example herein, particularly example 21, where the power substrate is substituted for a solid metal lead frame.

Example 26. The apparatus of any example herein, particularly example 25, where the lead frame is directly joined to the semiconductor device through a liquid metal interface material.

Example 27. The apparatus of any example herein, particularly example 21, where the above room temperature liquid metal is not melted through the normal operation of the semiconductor device, but via a predefined power loss routine designed to raise the temperature to the melting point of the above-room-temperature-liquid-metal.

Example 28. The apparatus of any example herein, particularly example 21, where the liquid metal interface materials contain particles such that the liquid metal interface material resembles a paste or foam.

Example 29. The apparatus of any example herein, particularly example 21, where the liquid metal materials are alloy based, for example a combination of gallium, indium, or bismuth alloys.

Example 30. The apparatus of any example herein, particularly example 21, where a room temperature liquid metal appends the semiconductor device to the electrically conductive connection device, and where the above-room-temperature-liquid-metal appends the semiconductor device to the power substrate.

Example 31. The apparatus of any example herein, particularly example 21, where both the power substrate and the electrically conductive connection device are appended to the semiconductor with room temperature liquid metal materials.

Example 32. The apparatus of any example herein, particularly example 21, where both the power substrate and the electrically conductive connection device are appended to the semiconductor with above room temperature liquid metal materials.

Example 33. The apparatus of any example herein, particularly example 21, where the encapsulation material comprises at least two materials. A soft, flexible, or low shore hardness encapsulation surrounding the liquid metal interfaces, and a hard, rigid, or high shore hardness encapsulation material surrounding the soft encapsulation.

Example 34. The apparatus of any example herein, particularly example 21, where the surface metallization on liquid metal interface contact areas is pre-aged to induce liquid metal intermetallic formation prior to assembly.

Example 35. The apparatus of any example herein, particularly example 21, where the liquid metal contact surfaces are coated with a metallization such as gold, silver, tantalum, titanium, or other material, that enhances liquid metal wetting or the adhesive force applied to the liquid metal interface material or prevents absorption of the liquid metal into the surface.

Example 36. The apparatus of any example herein, particularly example 21, where the surfaces that are not in contact with a liquid metal interface material have a surface treatment or coating that reduces the adhesive force and wettability of the liquid metal interface material.

Example 37. The apparatus of any example herein, particularly example 21, where the semiconductor device electrode aluminum metallization is coated with a layer such as gold, silver, tantalum, titanium, or other material combination, that enhances the adhesive force applied to the liquid metal material, enhances wetting, or prevents absorption of the liquid metal into the semiconductor device.

Example 38. The apparatus of any example herein, particularly example 217, where the semiconductor comprises a further coating of a non-wetting barrier layer around the edges of the electrode pads, which prevents contact between the aluminum and liquid metal.

Example 39. The apparatus of any example herein, particularly example 21, where semiconductor device electrodes contain only a diffusion barrier layer, with the electrode aluminum metallization replaced by a layer of liquid metal that wets the diffusion barrier metal layer.

Example 40. The apparatus of any example herein, particularly example 21, where the semiconductor device electrode pads can be surrounded by a guard ring in the region of 0 μm-100 μm in height.

Example 41. The apparatus of any example herein, particularly example 21, where a solid metal electrically conductive spacer is sandwiched between at least one electrically conductive connection device and at least one semiconductor device. The spacer is appended to the semiconductor device and the electrically conductive connection device via at least one layer of liquid metal.

Example 42. The apparatus of any example herein, particularly example 21, where a solid metal electrically conductive spacer is sandwiched between the power substrate and the semiconductor device. The spacer is appended to the semiconductor device and the power substrate via at least one layer of liquid metal.

Example 43. The apparatus of any example herein, particularly example 21, where the semiconductor package undergoes a burn-in process after manufacture, through vibration or thermal cycling, or other suitable method, to induce wetting of the liquid metal interface to the contact surfaces.

Example 44. The apparatus of any example herein, particularly example 21, where all liquid metal interface contact surfaces are pre-wetted with liquid metal prior to assembly.

Example 45. The apparatus of any example herein, particularly example 21, where the liquid metal interfaces not in direct contact with the semiconductor device comprise solder, sinter, or other conductive adhesive materials.

Example 46. The apparatus of any example herein, particularly example 21, where the above-room-temperature liquid metal comprises a solid interconnection such solder, sinter, or conductive adhesive material.

Example 47. The apparatus of any example herein, particularly example 21, where the power substrate comprises at least one dielectric layer and at least one conductive layer appended together using a liquid metal interface material.

Example 48. The apparatus of any example herein, particularly example 47, where the dielectric layer liquid metal contact areas are coated with a material that enhances the adhesive force applied to the liquid metal and increases wettability.

Example 49. The apparatus of any example herein, particularly example 21, where the baseplate is substituted for a heatsink.

Example 50. The apparatus of any example herein, particularly example 21, where the electrically conductive connection device comprises multiple conductive layers joined together with vias through a dielectric layer.

Example 51. The apparatus of any example herein, particularly example 50, where the vias are filled with liquid metal interface material or other conductive material.

Example 52. The apparatus of any example herein, particularly example 50, where the vias are capped or sealed on one or both sides of the via.

Example 53. The apparatus of any example herein, particularly example 21, without a pressure device.

Example 54. The apparatus of any example herein, particularly example 21, where the pressure device is the power terminal affixed to the baseplate or package housing.

Example 55. The apparatus of any example herein, particularly example 54, where the pressure device is the power terminal and a layer of liquid metal interface material appends the power terminal to the pressure area.

Example 56. The apparatus of any example herein, particularly example 54, where the pressure device is the power terminal and an elastic material encased by a hollow solid metal conductive sheet is compressed between the power terminal and the pressure area. The conductive sheet being appended to the pressure area and power terminal via liquid metal interface materials.

Example 57. The apparatus of any example herein, particularly example 21, where the pressure device is non-conductive and is an elastic, foam, or compressible material with a fixture that is affixed to the module housing or baseplate.

Example 58. A method for manufacturing a liquid interface semiconductor package, comprising:
a. Pre-wetting liquid metal interface contact areas with liquid metal,
b. Aging the liquid metal contact areas at an elevated temperature to induce intermetallic formation prior to assembly,
c. Re-wetting at least one liquid metal contact area,
d. Joining at least one liquid metal contact area,
e. Performing a first encapsulation that encases the joined liquid metal contact area, but leaving unwetted contact areas exposed,
f. Repeating steps c, d, and e as required,
g. Applying a pressure device,
h. Performing a final encapsulation.

Example 59. The method of any example herein, particularly example 58, where one encapsulation step is used.

Example 60. The method of any example herein, particularly example 58, where liquid metal contact areas are wetted and joined in order of highest melting temperature first.

Example 61. The method of any example herein, particularly example 58, where liquid metal contact areas are not pre-aged prior to assembly.

Example 62. The method of any example herein, particularly example 58, where liquid metal contact areas are wetted using scrubbing or friction.

Example 63. The method of any example herein, particularly example 58, where liquid metal contact areas are wetted using chemical methods.

Example 64. The method of any example herein, particularly example 58, where liquid metal contact areas are wetted using vibration or sonication.

Example 65. The method of any example herein, particularly example 58, where liquid metal contact areas are wetted using laser or plasma sintering.

Example 66. The method of any example herein, particularly example 58, where liquid metal contact areas are cleaned of liquid metal after aging.

Example 67. The method of any example herein, particularly example 58, where liquid metal interfaces are placed in a vacuum in their liquid state immediately after joining an interface.

Example 68. A liquid interconnect semiconductor package, comprising:
at least one semiconductor device with at least two electrodes
at least one solid metal lead frame
at least one solid metal electrically conductive connection device
a room temperature liquid metal interface material that appends at least one electrode of the semiconductor device to the lead frame
a low, above room temperature, liquid metal interface material that appends at least one electrode of the semiconductor device to at least one terminal of at least one electrically conductive connection device, with the above room temperature liquid metal interface being transitioned to liquid state by the normal operating power losses and temperature fluctuations of the semiconductor device
at least one electrically conductive connection device having at least one terminal attaching to a lead frame through a liquid metal interface material
an encapsulation material that encapsulates the semiconductor device, and liquid metal interfaces.

Example 69. The apparatus of any example herein, particularly example 68, where the liquid metal interfaces are below 25 μm in thickness.

Example 70. The apparatus of any example herein, particularly example 68, where the above room temperature liquid metal is not melted through the normal operation of the semiconductor device, but via a predefined power loss routine designed to raise the temperature to the melting point of the above-room-temperature-liquid-metal.

Example 71. The apparatus of any example herein, particularly example 68, where the liquid metal interface materials contain filler particles such that the liquid metal interface material resembles a paste or foam.

Example 72. The apparatus of any example herein, particularly example 68, where a room temperature liquid metal appends the semiconductor device to the electrically conductive connection device, and where the above-room-temperature-liquid-metal appends the semiconductor device to the lead frame.

Example 73. The apparatus of any example herein, particularly example 68, where both the lead frame and the electrically conductive connection device are appended to the semiconductor with a room temperature liquid metal

Example 74. The apparatus of any example herein, particularly example 68, where both the lead frame and the electrically conductive connection device are appended to the semiconductor with an above room temperature liquid metal.

Example 75. The apparatus of any example herein, particularly example 68, where the encapsulation material comprises two materials: a soft, flexible, or low shore hardness encapsulation surrounding the semiconductor device and liquid metal interfaces, and a high shore hardness encapsulation material surrounding the electrically conductive connection device and part of the lead frame.

Example 76. The apparatus of any example herein, particularly example 68, where the surface metallization of the lead frame, electrically conductive connection device, and semiconductor device, are provided pre-aged with intermetallic formation from the reaction of the surface metal with the liquid metal interface material. This may be performed on only the desired contact surfaces or on the entire surface of the devices.

Example 77. The apparatus of any example herein, particularly example 68, the lead frame and electrically conductive connection device, and contact surfaces on the semiconductor device are coated with a layer such as nickel, gold, silver, tantalum, titanium, or other material, that enhances liquid metal wetting or prevents absorption of the liquid metal into these devices.

Example 78. The apparatus of any example herein, particularly example 68, where semiconductor device surface metallization is removed and replaced by a layer of liquid metal, that wets the barrier metal layer. The semiconductor device may be surrounded by a polyimide guard ring in the region of 0 μm-100 μm in height.

Example 79. The apparatus of any example herein, particularly example 68, where the liquid metal materials are alloy based, for example a combination or gallium, indium, or bismuth alloys.

Example 80. The apparatus of any example herein, particularly example 68, where a solid metal electrically conductive spacer is sandwiched between at least one electrically conductive connection device and the semiconductor device. The spacer is appended to the semiconductor device and the electrically conductive connection device via at least one layer of liquid metal.

Example 81. The apparatus of any example herein, particularly example 68, where a solid metal electrically conductive spacer is sandwiched between the lead frame and the semiconductor device. The spacer is appended to the semiconductor device and the lead frame via at least one layer of liquid metal.

Example 82. The apparatus of any example herein, particularly example 68, where the semiconductor package undergoes a burn-in process, through vibration or thermal cycling, or other suitable method, to induce wetting of the liquid metal interface to the contact surfaces.

Example 83. The apparatus of any example herein, particularly example 68, where all liquid metal interface contact surfaces are pre-wetted with liquid metal via scrubbing, mechanical vibration, laser sintering, or other suitable method, prior to assembly.

Example 84. The apparatus of any example herein, particularly example 68, where the lead frame is substituted for a power substrate with a ceramic or flexible polymer insulation material.

Other advantages which are obvious and which are inherent to the invention will be evident to one skilled in the art. It will be understood that certain features and sub-combinations are of utility and may be employed without reference to other features and sub-combinations. This is contemplated by and is within the scope of the claims. Since many possible embodiments may be made of the invention without departing from the scope thereof, it is to be understood that all matter herein set forth or shown in the accompanying drawings is to be interpreted as illustrative and not in a limiting sense.

The methods of the appended claims are not limited in scope by the specific methods described herein, which are intended as illustrations of a few aspects of the claims and any methods that are functionally equivalent are intended to fall within the scope of the claims. Various modifications of the methods in addition to those shown and described herein are intended to fall within the scope of the appended claims. Further, while only certain representative method steps disclosed herein are specifically described, other combinations of the method steps also are intended to fall within the scope of the appended claims, even if not specifically recited. Thus, a combination of steps, elements, components, or constituents may be explicitly mentioned herein or less, however, other combinations of steps, elements, components, and constituents are included, even though not explicitly stated.

What is claimed is:

1. A semiconductor package device, comprising:
a semiconductor device comprising an electrode and/or contact pad;
a solid metal circuit element; and
a liquid metal interface comprising a liquid metal material;
wherein the liquid metal interface appends at least a portion of the solid metal circuit element to at least a portion of the electrode and/or contact pad within a contact area;
wherein adhesive forces, cohesive forces, surface tension forces, capillary forces, viscosity, and/or wetting characteristics enable containment of the liquid metal interface within the contact area.

2. The device of claim 1, wherein the liquid metal material comprises an alloy comprising gallium, indium, tin, bismuth, or a combination thereof.

3. The device of claim 1, wherein the liquid metal material comprises a room temperature liquid metal material, a low temperature liquid metal material, or a combination thereof.

4. The device of claim 1, wherein the device comprises a first liquid metal interface comprising a first liquid metal material and a second liquid metal interface comprising a second liquid metal material.

5. The device of claim 4, wherein the first liquid metal material transitions between liquid and solid at a first temperature, and the second liquid metal material is transitions between liquid and solid at second temperature, the first temperature being different than the second temperature.

6. The device of claim 1, wherein the liquid metal interface has a thickness of 25 μm or less.

7. The device of claim 1, wherein the liquid metal interface has a thickness of 10 micrometers or less.

8. The device of claim 1, wherein the liquid metal interface has a thickness and/or composition that varies.

9. The device of claim 1, wherein the liquid metal material further comprises filler particles, such that the liquid metal material resembles a paste or foam.

10. The device of claim 9, wherein the liquid metal material comprises a Ga-based paste.

11. The device of claim 1, wherein the liquid metal material comprises Ga and an additional metal such as palladium platinum, gold, silver, or a combination thereof.

12. The device of claim 1, wherein the portion of the semiconductor device and solid metal circuit element contacting the liquid metal interface are further coated with a metallization layer that enhances liquid metal wetting, enhances the adhesive force applied to the liquid metal interface material, prevents absorption of the liquid metal into the surface, or a combination thereof.

13. The device of claim 12, wherein the metallization layer comprises gold, silver, tantalum, titanium, platinum, palladium, nickel, or a combination thereof.

14. The device of claim 12, wherein at least a portion of the semiconductor device and solid metal circuit element are not in contact with the liquid metal interface, said portion of the semiconductor device and solid metal circuit element not contacting the liquid metal interface have a surface treatment or coating that reduces the adhesive force and wettability of the liquid metal interface material therewith.

15. The device of claim 1, further comprising a lead frame and an electrically conductive connection device, where a first liquid metal interface appends at least a portion of the semiconductor device to at least a portion of the electrically conductive connection device, and where a second liquid metal interface appends at least a portion of the semiconductor device to at least a portion of the lead frame.

16. The device of claim 1, further comprising an encapsulation material that encapsulates at least a portion of the semiconductor device and liquid metal interface.

17. The device of claim 1, further comprising a pressure device configured to apply a pressure to at least a portion of the device.

18. A method of making the device of claim 1.

19. The method of claim 18, wherein the method comprises, in the following order:
pre-wetting liquid metal interface contact areas with liquid metal,
aging the liquid metal contact areas to induce intermetallic formation prior to assembly,
re-wetting at least one liquid metal contact area, and
joining at least one liquid metal contact area.

20. The method of claim 18, wherein the liquid metal contact areas are wetted and joined in order of highest melting temperature first.
